(19) United States
(12) Patent Application Publication
(10) Pub. No.: US 2026/0271542 A1
(43) Pub. Date: Sep. 10, 2026

(54) DISPLAY DEVICE

(71) Applicant: Magnolia White Corporation, Tokyo (JP)

(72) Inventors: Sho YANAGISAWA, Tokyo (JP); Hitoshi TSUGE, Tokyo (JP); Hiroshi FUJIMURA, Tokyo (JP); Hiraaki KOKAME, Tokyo (JP)

(73) Assignee: Magnolia White Corporation, Tokyo (JP)

(21) Appl. No.: 19/558,831

(22) Filed: Mar. 6, 2026

(30) Foreign Application Priority Data
Mar. 6, 2025 (JP) 2025-035413

(51) Int. Cl. H10K 59/122; H10K 59/12; H10K 59/80

(52) U.S. Cl. CPC H10K 59/122; H10K 59/1201; H10K 59/873

(57) ABSTRACT

According to one embodiment, a display device includes an organic insulating layer provided over a display area and a surrounding area, a plurality of lower electrodes, a first partition including a first conductive lower portion, and a first upper portion, a plurality of stacked films each including an organic layer which covers the lower electrode, a first sealing layer formed of an inorganic insulating material to cover the plurality of stacked films, a dam structure provided above the organic insulating layer, surrounding the first partition, and protruding farther than the first partition, in the surrounding area, and a first resin layer provided inside the dam structure and covering the first sealing layer.

### CROSS-REFERENCE TO RELATED APPLICATION

This application is based upon and claims the benefit of priority from Japanese Patent Application No. 2025-035413, filed Mar. 6, 2025, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. In this type of display devices, a technique for improving the display quality is required.

### BRIEF DESCRIPTION OF THE DRAWINGS

FIG. 1 is a view showing a configuration example of a display device according to a first embodiment.

FIG. 2 is a schematic plan view showing an example of layout of subpixels constituting a pixel.

FIG. 3 is a schematic cross-sectional view showing the display device along III-III line in FIG. 2.

FIG. 4 is a schematic plan view showing a motherboard according to the first embodiment.

FIG. 5 is a schematic plan view showing a panel portion.

FIG. 6A is a schematic cross-sectional view showing the panel portion along VI-VI line in FIG. 5.

FIG. 6B is an enlarged view showing a vicinity of a dam structure in FIG. 6A.

FIG. 7 is a flowchart showing an example of a display device manufacturing method.

FIG. 8A is a schematic cross-sectional view showing a display device manufacturing process.

FIG. 8B is a schematic cross-sectional view showing a process following FIG. 8A.

FIG. 8C is a schematic cross-sectional view showing a process following FIG. 8B.

FIG. 8D is a schematic cross-sectional view showing a process following FIG. 8C.

FIG. 8E is a schematic cross-sectional view showing a process following FIG. 8D.

FIG. 8F is a schematic cross-sectional view showing a process following FIG. 8E.

FIG. 8G is a schematic cross-sectional view showing a process following FIG. 8F.

FIG. 8H is a schematic cross-sectional view showing a process following FIG. 8G.

FIG. 8I is a schematic cross-sectional view showing a process following FIG. 8H.

FIG. 8J is a schematic cross-sectional view showing a process following FIG. 8I.

FIG. 9A is a schematic cross-sectional view showing a display device manufacturing process.

FIG. 9B is a schematic cross-sectional view showing a process following FIG. 9A.

FIG. 9C is a schematic cross-sectional view showing a process following FIG. 9B.

FIG. 10 is a flowchart showing an example of a resin layer manufacturing process.

FIG. 11A is a schematic cross-sectional view showing the resin layer manufacturing process.

FIG. 11B is a schematic cross-sectional view showing a process following FIG. 11A.

FIG. 11C is a schematic cross-sectional view showing a process following FIG. 11B.

FIG. 12 is a schematic cross-sectional view showing a panel portion according to a second embodiment.

FIG. 13A is a schematic cross-sectional view showing a panel portion according to a third embodiment.

FIG. 13B is an enlarged view showing a vicinity of dams in FIG. 13A.

FIG. 14A is a diagram illustrating an example of an arrangement of a dam.

FIG. 14B is a diagram illustrating another example of an arrangement of a dam.

FIG. 14C is a diagram illustrating yet another example of an arrangement of a dam.

FIG. 14D is a diagram illustrating yet another example of an arrangement of a dam.

FIG. 15 is a flowchart showing an example of a display device manufacturing method according to the third embodiment.

FIG. 16A is a schematic cross-sectional view showing a panel portion according to a fourth embodiment.

FIG. 16B is an enlarged view showing a vicinity of a dam structure in FIG. 16A.

FIG. 17A is a schematic cross-sectional view showing a panel portion according to a fourth embodiment.

FIG. 17B is an enlarged view showing a vicinity of dams in FIG. 17A.

FIG. 18A is a schematic cross-sectional view showing a panel portion according to a fifth embodiment.

FIG. 18B is an enlarged view showing a vicinity of dams in FIG. 18A.

FIG. 19A is a flowchart showing an example of a display device manufacturing method according to the fifth embodiment.

FIG. 19B is a flowchart showing another example of a display device manufacturing method according to the fifth embodiment.

FIG. 19C is a flowchart showing yet another example of a display device manufacturing method according to the fifth embodiment.

FIG. 20A is a schematic cross-sectional view showing a panel portion according to a sixth embodiment.

FIG. 20B is an enlarged view showing a vicinity of dams in FIG. 20A.

FIG. 21 is a flowchart showing an example of a display device manufacturing method according to a sixth embodiment.

FIG. 22 is a schematic cross-sectional view showing a panel portion according to a seventh embodiment.

### DETAILED DESCRIPTION

In general, according to one embodiment, a display device comprises: a substrate having a display area and a surrounding area surrounding the display area; an organic insulating layer provided over the display area and the surrounding area above the substrate; a plurality of lower electrodes provided above the organic insulating layer in the display area; an inorganic insulating layer including a plurality of pixel apertures overlapping with the plurality of lower electrodes, respectively; a first partition including a first conductive lower portion provided above the inorganic insulating layer, and a first upper portion having an end portion protruding from a side surface of the first lower portion, and surrounding each of the plurality of pixel apertures; a plurality of stacked films each including an organic layer which covers the lower electrode through the pixel aperture and which emits light in accordance with application of a voltage; a first sealing layer formed of an inorganic insulating material to cover the plurality of stacked films; a dam structure provided above the organic insulating layer, surrounding the first partition, and protruding farther than the first partition, in the surrounding area; and a first resin layer provided inside the dam structure and covering the first sealing layer.

According to another embodiment, a display device comprises: a substrate having a display area and a surrounding area surrounding the display area; an organic insulating layer provided over the display area and the surrounding area above the substrate; a plurality of lower electrodes provided above the organic insulating layer in the display area; an inorganic insulating layer including a plurality of pixel apertures overlapping with the plurality of lower electrodes, respectively; a first partition including a first conductive lower portion provided above the inorganic insulating layer, and a first upper portion having an end portion protruding from a side surface of the first lower portion, surrounding each of the plurality of pixel apertures in the display area, and provided from the display area to the surrounding area; a plurality of stacked films each including an organic layer which covers the lower electrode through the pixel aperture and which emits light in accordance with application of a voltage; a first sealing layer formed of an inorganic insulating material to cover the plurality of stacked films; a dam structure provided above the first partition in the surrounding area; and a first resin layer provided inside the dam structure and covering the first sealing layer.

According to the configurations, a display device capable of improving the display quality can be provided.

Embodiments will be described hereinafter with reference to the accompanying drawings. The disclosure is a mere example, and arbitrary change of gist which can be easily conceived by a person of ordinary skill in the art naturally falls within the inventive scope. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

Incidentally, in the drawings, in order to facilitate understanding, an X-axis, a Y-axis and a Z-axis orthogonal to each other are shown as needed. A direction parallel to the X-axis is referred to as an X-direction. A direction parallel to the Y-axis is referred to as a Y-direction. A direction parallel to the Z-axis is referred to as a Z-direction. Viewing various elements in a direction parallel to the Z-direction is referred to as plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

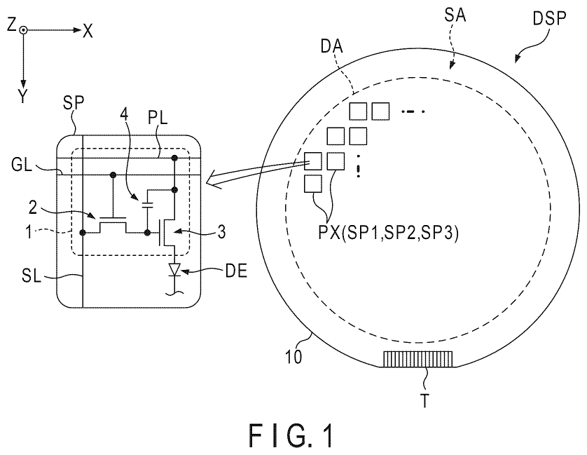

FIG. 1 is a view showing a configuration example of a display device DSP according to the present embodiment. The display device DSP comprises an insulating substrate 10. The substrate 10 has a display area DA where images are displayed, and a surrounding area SA which surrounds the display area DA. The substrate 10 may be glass or a resinous film having flexibility.

In the present embodiment, the substrate 10 and the display area DA have a circular shape in plan view. Incidentally, the circular shape implies an oval, an ellipse, and a partially cutaway shape in addition to a perfect circle. In addition, the shape of the substrate 10 and the display area DA in plan view is not limited to a circle, but may be the other shape such as a rectangle, a square or an ellipse.

The display area DA comprises a plurality of pixels PX arrayed in matrix in the X-direction and the Y-direction. Each pixel PX includes a plurality of subpixels SP which display different colors. In the present embodiment, it is assumed that each pixel PX includes a blue subpixel SP1, a green subpixel SP2, and a red subpixel SP3. Each pixel PX may include a subpixel SP which displays the other color such as white in addition to the subpixels SP1, SP2 and SP3 or instead of one of the subpixels SP1, SP2 and SP3.

The display device DSP further comprises a terminal portion T provided in the surrounding area SA. For example, a flexible printed circuit which applies voltage and signals for driving the display device DSP is connected to the terminal portion T.

Each subpixel SP comprises a pixel circuit 1 and a display element DE driven by the pixel circuit 1. The pixel circuit 1 comprises a pixel switch 2, a drive transistor 3, and a capacitor 4. Each of the pixel switch 2 and the drive transistor 3 is, for example, a switching element which consists of a thin-film transistor.

A plurality of scanning lines GL which supply scanning signals to the pixel circuit 1 of each subpixel SP, a plurality of signal lines SL which supply video signals to the pixel circuit 1 of each subpixel SP and a plurality of power lines PL are provided in the display area DA. In the example of FIG. 1, the scanning lines GL and the power lines PL extend in the X-direction, and the signal lines SL extend in the Y-direction.

A gate electrode of the pixel switch 2 is connected to the scanning line GL. One of a source electrode and a drain electrode of the pixel switch 2 is connected to the signal line SL. The other electrode is connected to a gate electrode of the drive transistor 3 and the capacitor 4. In the drive transistor 3, one of a source electrode and a drain electrode is connected to the power line PL and the capacitor 4, and the other electrode is connected to the display element DE.

Incidentally, the configuration of the pixel circuit 1 is not limited to the example shown in the figure. For example, the pixel circuit 1 may comprise more thin-film transistors and more capacitors.

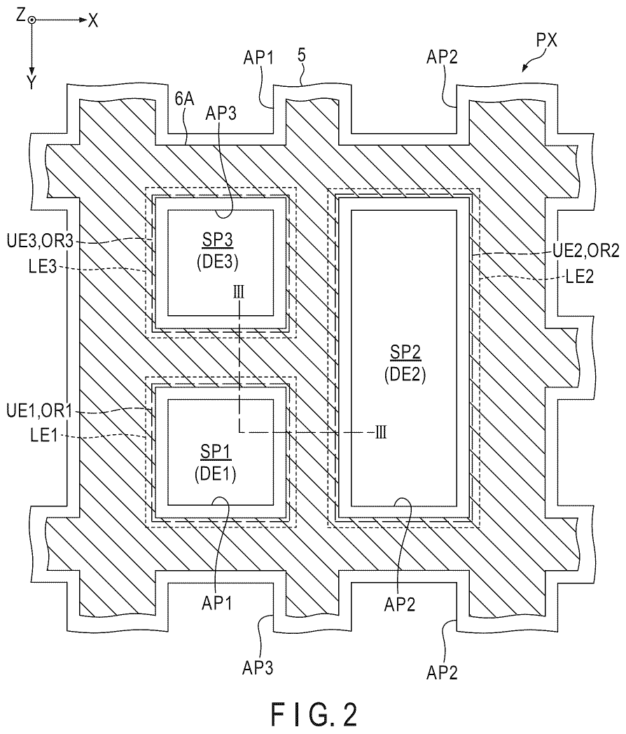

FIG. 2 is a schematic plan view showing an example of the layout of the subpixels SP1, SP2 and SP3 constituting one pixel PX. In the example of FIG. 2, the subpixels SP1 and SP3 are arranged in the Y-direction. In addition, each of the subpixels SP1 and SP3 is adjacent to the subpixel SP2 in the X-direction.

When the subpixels SP1, SP2, and SP3 are provided in this layout, a column in which the subpixels SP1 and SP3 are alternately provided in the Y-direction and a column in which a plurality of subpixels SP2 are repeatedly provided in the Y-direction are formed in the display area DA. These columns are alternately arranged in the X-direction. Incidentally, the layout of the subpixels SP1, SP2, and SP3 is not limited to the example of FIG. 2.

A rib layer 5 (inorganic insulating layer) is provided in the display area DA. The rib layer 5 includes pixel apertures AP1, AP2, and AP3 in the subpixels SP1, SP2, and SP3, respectively. In the example of FIG. 2, the pixel apertures AP1 and AP3 have rectangular shapes which are the same in area. In contrast, the pixel aperture AP2 has a rectangular shape which is more elongated in the Y-direction than the pixel apertures AP1 and AP3. However, the shape of the pixel apertures AP1, AP2, and AP3 is not limited to this example.

The subpixel SP1 comprises a lower electrode LE1, an upper electrode UE1, and an organic layer OR1 each overlapping with the pixel aperture AP1. The subpixel SP2 comprises a lower electrode LE2, an upper electrode UE2, and an organic layer OR2 each overlapping with the pixel aperture AP2. The subpixel SP3 comprises a lower electrode LE3, an upper electrode UE3, and an organic layer OR3 each overlapping with the pixel aperture AP3.

Of the lower electrode LE1, the upper electrode UE1, and the organic layer OR1, the portions which overlap with the pixel aperture AP1 constitute the display element DE1 of the subpixel SP1. Of the lower electrode LE2, the upper electrode UE2, and the organic layer OR2, the portions which overlap with the pixel aperture AP2 constitute the display element DE2 of the subpixel SP2. Of the lower electrode LE3, the upper electrode UE3, and the organic layer OR3, the portions which overlap with the pixel aperture AP3 constitute the display element DE3 of the subpixel SP3. Each of the display elements DE1, DE2, and DE3 may further include a cap layer to be described later. The rib layer 5 surrounds each of these display elements DE1, DE2, and DE3.

A conductive partition 6A (first partition) is provided above the rib layer 5. The partition 6A functions as lines which apply a common voltage to the upper electrodes UE1, UE2, and UE3. The partition 6A overlaps with the rib layer 5 as a whole and has a planar shape similar to that of the rib layer 5. The partition 6A surrounds each of the pixel apertures AP1, AP2, and AP3.

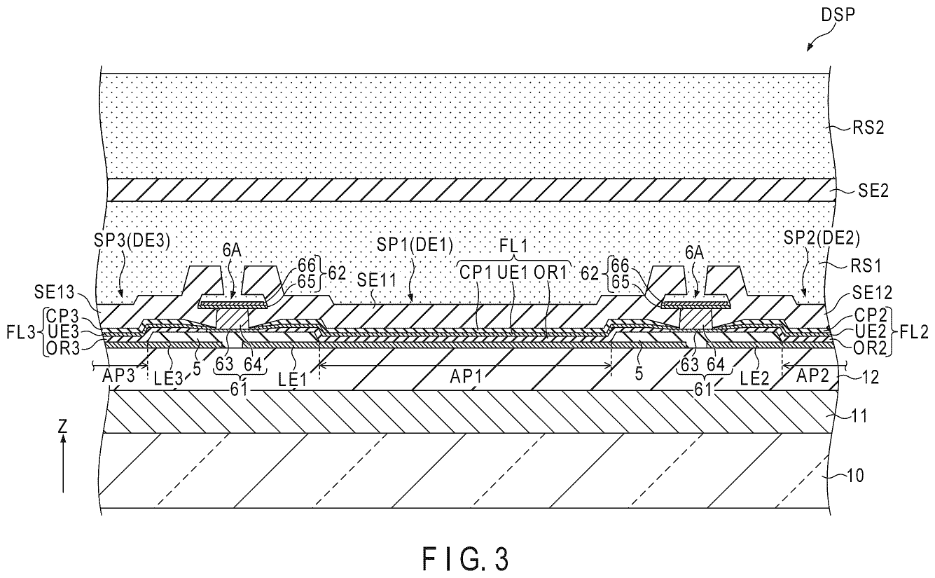

FIG. 3 is a schematic cross-sectional view showing the display device DSP along III-III line in FIG. 2. A circuit layer 11 is provided on the above-described substrate 10. The circuit layer 11 includes various circuits and lines such as the pixel circuit 1, the scanning line GL, the signal line SL, and the power line PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the cross-section of FIG. 3, the lower electrodes LE1, LE2, and LE3 are connected to the respective pixel circuits 1 of the circuit layer 11 through contact holes provided in the organic insulating layer 12.

The partition 6A includes a conductive lower portion 61 (first lower portion) provided on the rib layer 5 and an upper portion 62 (first upper portion) provided on the lower portion 61. The upper portion 62 has a width greater than that of the lower portion 61. In other words, the partition 6A has an overhang shape in which the both end portions of the upper portion 62 protrude relative to the side surfaces of the lower portion 61.

In the example of FIG. 3, the lower portion 61 has a bottom layer 63 provided on the rib layer 5, and a stem layer 64 provided on the bottom layer 63. For example, the bottom layer 63 is formed to be thinner than the stem layer 64. In the example of FIG. 3, the both end portions of the bottom layer 63 protrude from the side surfaces of the stem layer 64.

In addition, in the example of FIG. 3, the upper portion 62 comprises a first top layer 65, and a second top layer 66 provided on the first top layer 65. For example, the width of the second top layer 66 is slightly smaller than that of the first top layer 65. The configuration is not limited to this example, but the first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the lower portions 61 of the partition 6A.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2, and CP3 function as optical adjustment layers which improve the extraction efficiency of the light emitted from the organic layers OR1, OR2, and OR3, respectively.

In the following descriptions, a multilayer body including the organic layer OR1, the upper electrode UE1, and the cap layer CP1 is referred to as a stacked film FL1. A multilayer body including the organic layer OR2, the upper electrode UE2, and the cap layer CP2 is referred to as a stacked film FL2. A multilayer body including the organic layer OR3, the upper electrode UE3, and the cap layer CP3 is referred to as a stacked film FL3. The stacked films FL1, FL2, and FL3 are provided in the pixel apertures AP1, AP2, and AP3, respectively.

Sealing layers SE11, SE12, and SE13 (first sealing layers) are provided in the subpixels SP1, SP2, and SP3, respectively. The sealing layer SE11 continuously covers the display element DE1 and the partition 6A around the display element DE1. The sealing layer SE12 continuously covers the display element DE2 and the partition 6A around the display element DE2. The sealing layer SE13 continuously covers the display element DE3 and the partition 6A around the display element DE3.

In the example of FIG. 3, the sealing layer SE11 located on the partition 6A between the subpixels SP1 and SP2 is spaced apart from the sealing layer SE12 located on this partition 6A. In addition, the sealing layer SE11 located on the partition 6A between the subpixels SP1 and SP3 is spaced apart from the sealing layer SE13 located on the partition 6A. However, two of the sealing layers SE11, SE12, and SE13 may be in contact with each other above the partition 6A.

For example, a gap is formed between each of the sealing layers SE11, SE12, and SE13 and the upper portion 62 of the partition 6A. The stacked films FL1, FL2, and FL3 may be provided in at least parts of these gaps.

The sealing layers SE11, SE12, and SE13 are covered with a resin layer RS1 (first resin layer). The resin layer RS1 is covered with a sealing layer SE2 (second sealing layer). The sealing layer SE2 is covered with a resin layer RS2. The resin layers RS1 and RS2 and the sealing layer SE2 are continuously provided in at least the entire display area DA and partially extend to the surrounding area SA.

A cover member such as a polarizer, a touch panel, a protective film, or a cover glass may be further provided above the resin layer RS2. This cover member may be attached to the resin layer RS2 via, for example, an adhesive layer such as an optical clear adhesive (OCA).

The electrodes which constitute the above-described touch panel may be provided on the sealing layer SE2. In addition, color filters corresponding to the colors of the subpixels SP1, SP2, and SP3 may be provided above the display elements DE1, DE2, and DE3, respectively.

The organic insulating layer 12 is formed of an organic insulating material such as polyimide. Each of the rib layer 5 and the sealing layers SE11, SE12, SE13, and SE2 is formed of an inorganic insulating material such as silicon nitride (SiNx), silicon oxide (SiOx) or silicon oxynitride (SiON). In one example, the rib layer 5 is formed of silicon oxynitride, and each of the sealing layers SE11, SE12, SE13, and SE2 is formed of silicon nitride. Each of the resin layers RS1 and RS2 is formed of, for example, a resinous material (organic insulating material) such as epoxy resin or acrylic resin.

Each of the lower electrodes LE1, LE2, and LE3 includes a reflective layer formed of, for example, silver, and a pair of conductive oxide layers covering upper and lower surfaces of the reflective layer. Each of the conductive oxide layers can be formed of, for example, a transparent conductive oxide such as indium tin oxide (ITO), indium zinc oxide (IZO), indium gallium zinc oxide (IGZO), or the like.

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 consists of a plurality of thin films including a light emitting layer. In one example, each of the organic layers OR1, OR2, and OR3 comprises a structure in which a hole injection layer, a hole transport layer, an electron blocking layer, a light emitting layer, a hole blocking layer, an electron transport layer and an electron injection layer are stacked in order in the Z-direction. However, each of the organic layers OR1, OR2, and OR3 may comprise an alternative structure such as a so-called tandem structure including a plurality of light emitting layers.

Each of the cap layers CP1, CP2, and CP3 may comprise, for example, a multilayer structure in which a plurality of transparent layers are stacked. These transparent layers may include a layer formed of an inorganic material and a layer formed of an organic material. In addition, the transparent layers have refractive indices different from each other. For example, the refractive indices of these transparent layers are different from the refractive indices of the upper electrodes UE1, UE2, and UE3 and the refractive indices of the sealing layers SE11, SE12, and SE13. Incidentally, at least one of the cap layers CP1, CP2, and CP3 may be omitted.

The bottom layer 63 and the stem layer 64 of the partition 6A are formed of a metal material. For the metal material of the bottom layer 63, for example, molybdenum, titanium, titanium nitride (TiN), molybdenum-tungsten alloy (MoW), or molybdenum-niobium alloy (MoNb) can be used. For the metal material of the stem layer 64, for example, aluminum, an aluminum-neodymium alloy (AlNd), aluminum-yttrium alloy (AlY), or aluminum-silicon alloy (AlSi) can be used. Incidentally, the stem layer 64 may be formed of an insulating material.

The first top layer 65 of the partition 6A is formed of, for example, a metal material. In addition, the second top layer 66 of the partition 6A is formed of, for example, a conductive oxide. For the metal material forming the first top layer 65, for example, titanium, titanium nitride, molybdenum, tungsten, molybdenum-tungsten alloy, or molybdenum-niobium alloy can be used. For the conductive oxide forming the second top layer 66, for example, ITO or IZO can be used. Incidentally, the upper portion 62 may include three or more layers or may be composed of a single layer. Furthermore, the upper portion 62 may include a layer formed of an insulating material.

A common voltage is applied to the partition 6A. This common voltage is applied to each of the upper electrodes UE1, UE2, and UE3 which are in contact with the lower portion 61. Pixel voltages corresponding to the video signals of the signal lines SL are applied to the lower electrodes LE1, LE2, and LE3 through the pixel circuits 1 provided in the subpixels SP1, SP2, and SP3, respectively.

The organic layers OR1, OR2, and OR3 emit light based on the application of voltages. More specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light exhibiting the same color (for example, white). In this case, the display device DSP may comprise color filters which convert the light emitted from the light emitting layers into light exhibiting colors corresponding to the subpixels SP1, SP2, and SP3. In addition, the display device DSP may comprise a layer including a quantum dot which generates light exhibiting colors corresponding to the subpixels SP1, SP2, and SP3 by the excitation caused by the light emitted from the light emitting layers.

When the display device DSP is manufactured, a large-scaled motherboard on which a plurality of areas (panel portions) each corresponding to the display device DSP are formed is prepared. A configuration which can be applied to this motherboard will be described below.

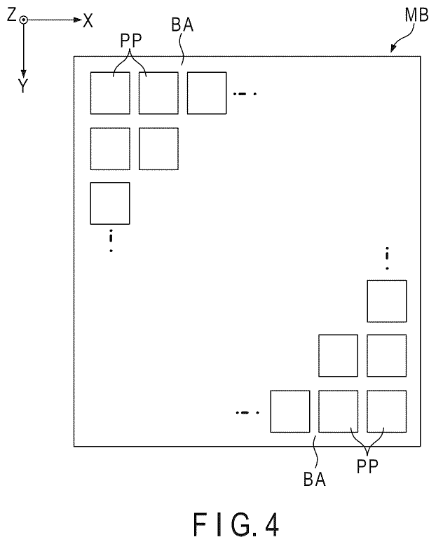

FIG. 4 is a schematic plan view showing a motherboard MB (motherboard for display device) according to the present embodiment. The motherboard MB has, for example, a rectangular shape as shown in the figure, but may have the other shape such as a circle.

The motherboard MB comprises a plurality of panel portions PP provided in matrix, and a margin area BA around these panel portions PP. In the example of FIG. 4, the panel portions PP are arranged via the margin area BA in the X-direction and the Y-direction. However, the layout form of the plurality of panel portions PP on the motherboard MB is not limited to this example. As the other example, several panel portions PP may be arranged without intervention of the margin area BA.

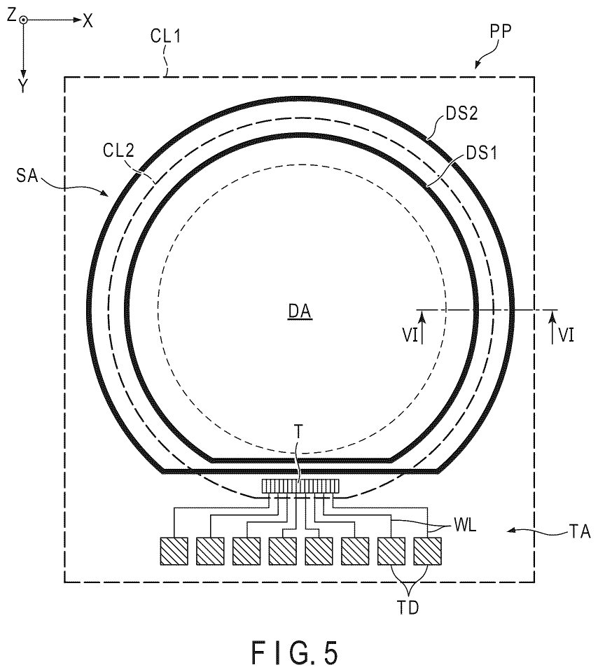

FIG. 5 is a schematic plan view showing the panel portion PP. The outer shape of the panel portion PP corresponds to a cut line CL1 for cutting the panel portion PP from the motherboard MB. The panel portion PP has the display area DA and the surrounding area SA as described above. The surrounding area SA in the panel portion PP corresponds to the area located between the display area DA and the cut line CL1.

The surrounding area SA further includes a cut line CL2 which is the outer shape of the substrate 10 of the display device DSP. The surrounding area SA includes an inspection area TA between the cut lines CL1 and CL2. A plurality of inspection pads TD for inspecting operations of the display panel PNL are provided in the inspection area TA. Each inspection pad TD is connected to the terminal portion T via a line WL.

When the display device DSP is manufactured, the panel portion PP is cut out from the motherboard MB along the cut line CL1. Furthermore, the cut panel portion PP is inspected, and then the inspection area TA is cut away from the panel portion PP along the cut line CL2.

The panel portion PP comprises dam structures DS1 and DS2. Each of the dam structure DS1 and the dam structure DS2 is formed in an annular shape. The dam structure DS1 is located between the cut line CL2 and the display area DA in the surrounding area SA and surrounds the display area DA. The dam structure DS2 is formed to surround the dam structure DS1 and is separated from the dam structure DS1. The dam structure DS2 is located in the inspection area TA.

A large part of the cut line CL2 is located between the dam structures DS1 and DS2. In the example of FIG. 5, however, the cut line CL2 is located outside the dam structures DS1 and DS2 near the terminal portion T. In other words, the cut line CL2 intersects the dam structure DS2 near the terminal portion T.

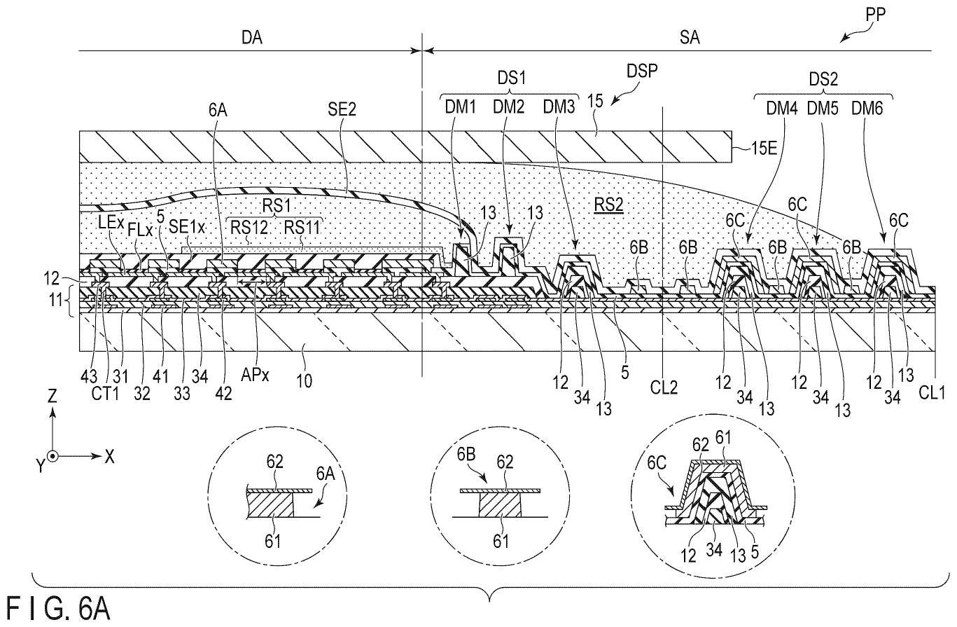

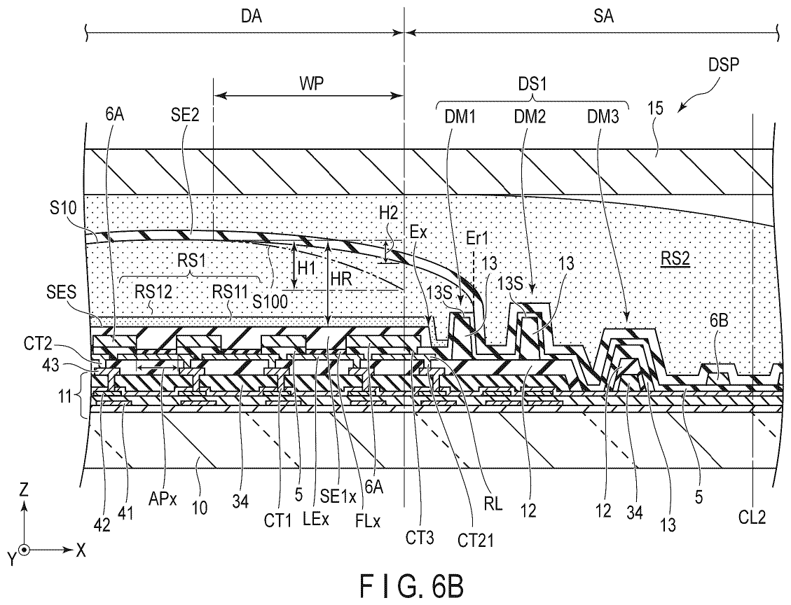

FIG. 6A is a schematic cross-sectional view showing the panel portion PP along VI-VI line in FIG. 5. FIG. 6B is an enlarged view showing a vicinity of a dam structure DS1 in FIG. 6A. FIG. 6A shows a cross-sectional structure of the panel portion PP. The structure inside the cut line CL2 corresponds to the cross-sectional structure of the area including the dam structure DS1 on the display device DSP.

As shown in FIG. 6A, the circuit layer 11 is provided from the display area DA to the surrounding area SA above the substrate 10. The circuit layer 11 is provided between the cut line CL1 and the cut line CL2 in the surrounding area SA.

The circuit layer 11 shown in FIG. 3 includes inorganic insulating layers 31, 32, and 33 formed of an inorganic insulating material, an organic insulating layer 34 formed of an organic insulating material, and metal layers 41, 42, and 43. The inorganic insulating layer 31 covers the upper surface of the substrate 10.

The metal layer 41 is provided on the inorganic insulating layer 31. The metal layer 41 is, for example, a layer including the scanning lines GL. The inorganic insulating layer 32 covers the metal layer 41. The metal layer 42 is provided on the inorganic insulating layer 32. The inorganic insulating layer 33 covers the metal layer 42. The metal layer 42 is, for example, a layer including the signal lines SL.

The organic insulating layer 34 covers the inorganic insulating layer 33. The metal layer 43 is provided on the organic insulating layer 34 and is covered with the organic insulating layer 12. The metal layer 43 is electrically connected with the metal layer 42 via a contact portion CT1 formed in the organic insulating layer 34.

The organic insulating layers 34 and 12 are partially formed even in the surrounding area SA. The organic insulating layers 34 and 12 are continuously provided over the display area DA and the surrounding area SA. The organic insulating layer 12 covers end portions of the organic insulating layer 34. An organic insulating layer 13 is further provided in the surrounding area SA. The organic insulating layer 13 is formed of an organic insulating material such as polyimide.

As described above, the panel portion PP comprises dam structures DS1 and DS2. When the display device DSP is manufactured, the dam structure DS1 plays a role of damming up the resin layer RS1 to be cured. The dam structure DS2 plays a role of damming up the resin layer RS2 to be cured.

The dam structure DS1 is located between the cut line CL2 and the display area DA in the surrounding area SA. The dam structure DS1 includes dams DM1 and DM2 provided on the organic insulating layer 12, and a dam DM3 provided on the circuit layer 11 (inorganic insulating layer 33).

The dams DM1 and DM2 are formed by the organic insulating layer 13. In the present embodiment, the dams DM1 and DM2 are formed of the same material as the organic insulating layer 13 and are formed in the same layer as the organic insulating layer 13.

The dams DM1 and DM2 surround a partition 6A and protrude upward beyond the partition 6A. Parts of the metal layers 41 and 42 (circuits including the metal layers 41 and 42) may be provided below the dams DM1 and DM2.

The dam structure DS2 is located in the surrounding area SA, between the cut line CL2 and the cut line CL1. The dam structure DS2 includes dams DM4, DM5, and DM6 provided on the circuit layer 11 (inorganic insulating layer 33).

Each of the dams DM1 to DM6 protrudes to the upper side of the substrate 10. The dams DM1 and DM2 are located at positions higher than the other dams DM3 through DM6. The dams DM1 and DM2 are, for example, formed in steps different from those used for dams DM3 to DM6.

The dams DM3 to DM6 are formed by the organic insulating layers 34 and 12. In the present embodiment, the dams DM3 to DM6 are formed of the same material as the organic insulating layers 34 and 12 and are formed in the same layer as the organic insulating layers 34 and 12. Furthermore, the dams DM3 to DM6 are covered with the organic insulating layer 13.

In the display area DA, a lower electrode LEx is provided on the organic insulating layer 12. The lower electrode LEx corresponds to one of the lower electrodes LE1, LE2, and LE3 shown in FIG. 3. The lower electrode LEx is electrically connected with the metal layer 43 via the contact portion CT2 (shown in FIG. 6B) formed in the organic insulating layer 12.

In addition, a part of the lower electrode LEx (shown as the relay layer RL in FIG. 6B) is formed to extend to the surrounding area SA. The relay layer RL is located on the display area DA side relative to the dam portion DM1 and covers the organic insulating layer 12.

The relay layer RL is electrically connected with the metal layer 43 via a contact portion CT21 formed in the organic insulating layer 12. The contact portion CT21 is located between the display area DA and the dam DM1. Connecting the relay layer RL and the metal layer 43 at this position can reduce a risk of the breakage in the relay layer RL.

In the display area DA, a rib layer 5 is provided on the lower electrode LEx. The rib layer 5 has a pixel aperture APx. The pixel aperture APx correspond to one of the pixel apertures AP1, AP2, and AP3 shown in FIG. 2 and FIG. 3. In addition, the rib layer 5 covers the surrounding area SA. More specifically, as shown in FIG. 6A, the rib layer 5 continuously covers the relay layer RL and the dams DM1 to DM6.

In the display area DA, a partition 6A is provided on the rib layer 5. As described above, the partition 6A includes a lower portion 61 (bottom layer 63 and stem layer 64) and an upper portion 62 (first top layer 65 and second top layer 66).

A part of the partition 6A is provided on the relay layer RL in the surrounding area SA. An end portion of the partition 6A has a shape enlarged and shown in the lower part of FIG. 6A. In addition, this partition 6A is electrically connected with the relay layer RL via a contact portion CT3 (shown in FIG. 6B) formed in the rib layer 5. More specifically, the lower portion 61 (more specifically, the bottom layer 63) of the partition 6A is in contact with the relay layer RL.

In addition, a partition 6B (second partition) and a partition 6C are provided in the surrounding area SA. The partitions 6B and 6C are provided outward from the dam structure DS1. The partition 6B is provided between the dam DM3 and the dam DM4, between the dam DM4 and the dam DM5, and between the dam DM5 and the dam DM6. A plurality of (for example, two) partitions 6B are arranged on either side of the cut line CL2 between the dam DM3 and the dam DM4. The partitions 6B are formed along the dam structures DS1 and DS2, and the cut line CL2.

The partitions 6B are provided on the rib layer 5. As enlarged in a lower part of FIG. 6A, the partition 6B includes a lower portion 61 (bottom layer 63 and stem layer 64) and an upper portion 62 (first top layer 65 and second top layer 66). In the present embodiment, the lower portion 61 of the partition 6B corresponds to a second lower portion, and the upper portion 62 of partition 6B corresponds to a second upper portion.

The partition 6C covers each of the dams DM4 to DM6. More specifically, the partition 6C covers each of the dams DM4 to DM6 via the rib layer 5. As enlarged in a lower part of FIG. 6A, the partition 6C includes a lower portion 61 (bottom layer 63 and stem layer 64) and an upper portion 62 (first top layer 65 and second top layer 66).

In the display area DA, a stacked film FLx is provided on the lower electrode LEx. The stacked film FLx and the partition 6A are covered with a sealing layer SE1x (first sealing layer). The shapes of the partition 6A, the stacked film FLx, and the sealing layer SE1x in the display area DA have been described with reference to FIG. 3. Incidentally, the stacked film FLx may be provided between the partition 6A and the sealing layer SE1x.

The stacked film FLx is formed of the same material as one of the stacked films FL1, FL2, and FL3 shown in FIG. 3 and is formed in the same process as one of the stacked films FL1, FL2, and FL3. The sealing layer SE1x is formed of the same material as one of the sealing layers SE11, SE12, and SE13 shown in FIG. 3 and is formed in the same process as one of the sealing layers SE11, SE12, and SE13.

When focusing on the dams DM1 and DM2, the dams DM1 and DM2 are not covered with the stacked film FLx or the sealing layer SE1x. The end portion Ex (second end portion) of the sealing layer SE1x is located on the display area DA side relative to the dam DM1.

The resin layer RS1 and the sealing layer SE2 shown in FIG. 3 are provided above the sealing layer SE1x. The resin layer RS1 covers the sealing layer SE1x and the rib layer 5. The resin layer RS1 is provided inside the dam structure DS1.

In the example of FIG. 6B, the end portion Er1 of the resin layer RS1 is located above the dam portion DM1. In other words, the resin layer RS1 covers a part of the dam DM1. However, the position of the end portion Er1 is not limited to this example. The resin layer RS1 is surrounded by the sealing layer SE1x, the rib layer 5, and the sealing layer SE2. Impregnation of moisture into the resin layer RS1 is thereby suspended.

The sealing layer SE2 covers the end portion Er1 of the resin layer RS1. The sealing layer SE2 is in contact with the rib layer 5 in an area located in an outer side relative to the end portion Er1. More specifically, as shown in FIG. 6A, the sealing layer SE2 covers the dams DM2 to DM6 and the partitions 6B and 6C. In the surrounding area SA, the area where the sealing layer SE2 is in contact with the rib layer 5 corresponds to a moisture barrier area which suppresses impregnation of moisture into the resin layer RS1.

Furthermore, in the example of FIG. 6A, a polarizer 15 is provided above the sealing layer SE2. The end portion 15E of the polarizer 15 is located, for example, between the cut line CL2 and the cut line CL1.

Attention will be paid to a relationship between the dams DM1 and DM2 and the other elements. The upper surfaces 13S of the dams DM1 and DM2 are located at positions higher than an upper surface SES of the sealing layer SE1x, as shown in FIG. 6B. In the example of FIG. 6A, the height of the dam DM1 is equal to the height of the dam DM2, but the height of the dam DM1 may be different from the height of the dam DM2. For example, the height of the dam DM1 may be greater than the height of the dam DM2 or the height of the dam DM1 may be smaller than the height of the dam DM2.

In this case, the height of the dams DM1 and DM2 corresponds to, for example, the distance in the Z-direction from the upper surface of the organic insulating layer 12 to the upper surfaces 13S of the dams DM1 and DM2. In addition, the height of the resin layer RS1 is shown as height HR (shown in FIG. 6B). The height HR is the distance from the upper surface SES of the sealing layer SE1x to an apex of the resin layer RS1. The apex is the position where the thickness is greatest in the resin layer RS1, and overlaps with, for example, the area where a resin layer RS11 to be described later is formed.

The height of the dams DM1 and DM2 is desirably greater than the height HR of the resin layer RS1. Due to manufacturing constraints, however, it may be difficult to make the height of the dams DM1 and DM2 greater than the height HR of the resin layer RS1. In such cases, the height HR of the resin layer RS1 is desirably, for example, approximately three to five times the height of the dams DM1 and DM2. The resin layer RS1 to be cured can be thereby dammed.

Furthermore, the cross-sectional structure shown in FIG. 6A can be applied to any position in the surrounding area SA, except the vicinity of the terminal portion T. However, the structure of the surrounding area SA is not necessarily limited to that shown in FIG. 6A.

Next, an example of the method of manufacturing the display device DSP will be described. When the display device DSP is manufactured, a large-scaled motherboard on which a plurality of areas (panel portions) each including a part corresponding to the display device DSP are formed is prepared.

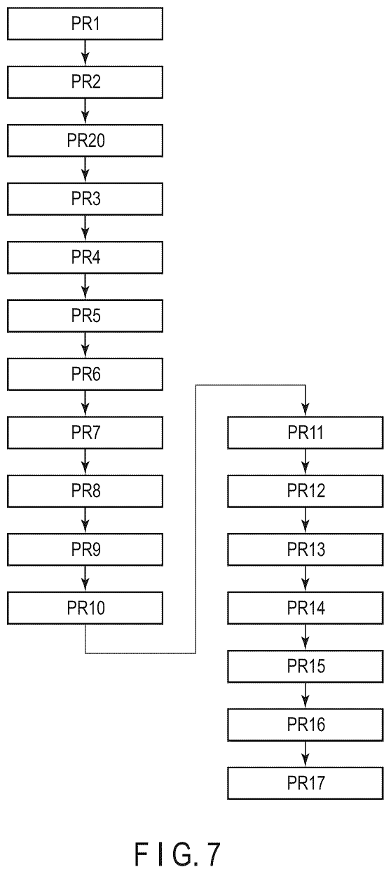

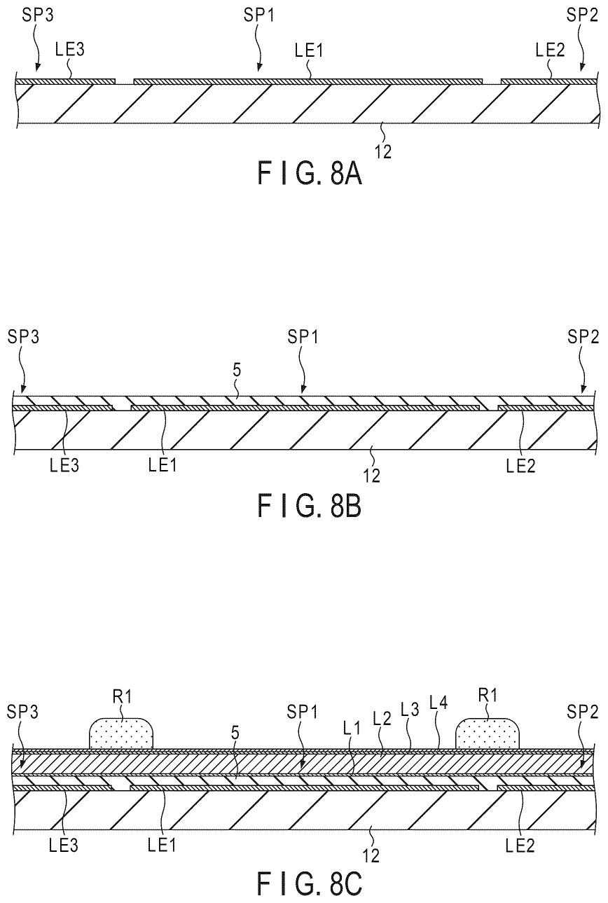

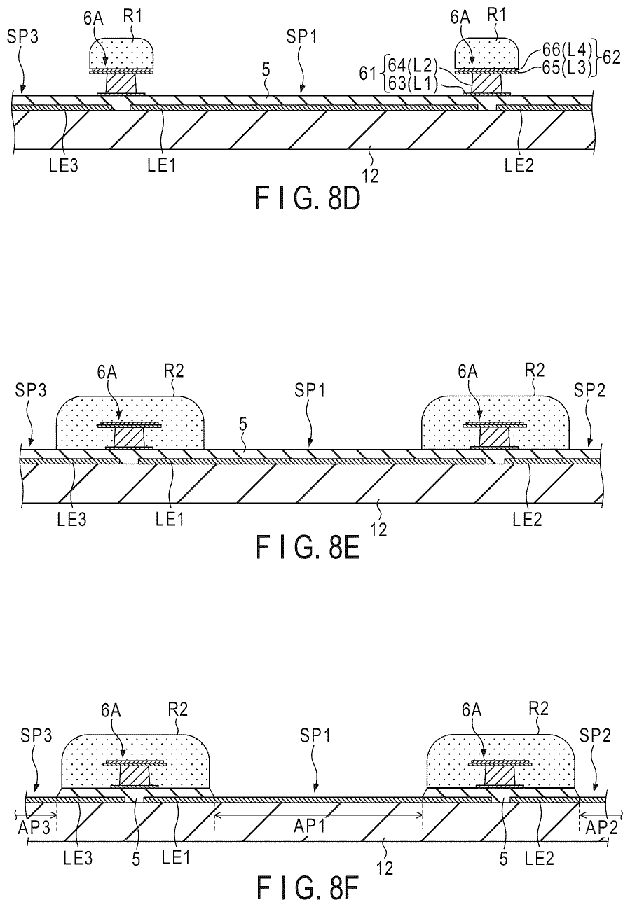

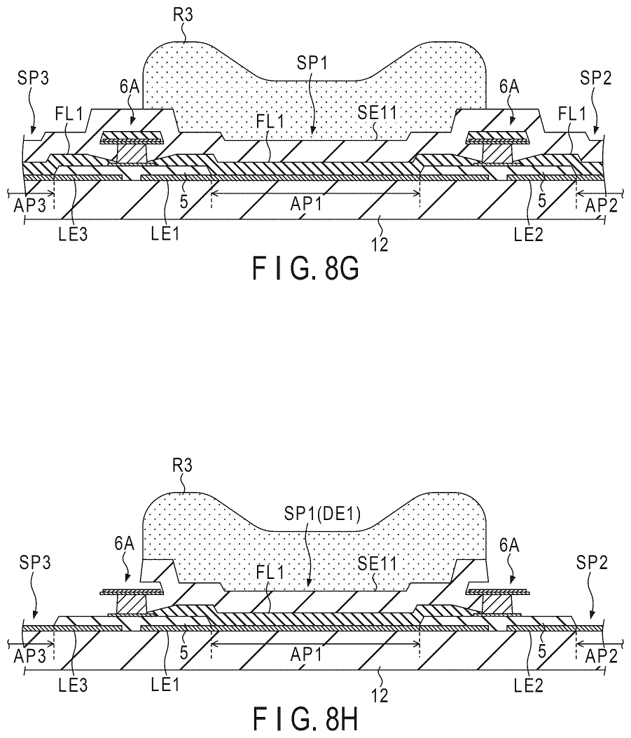

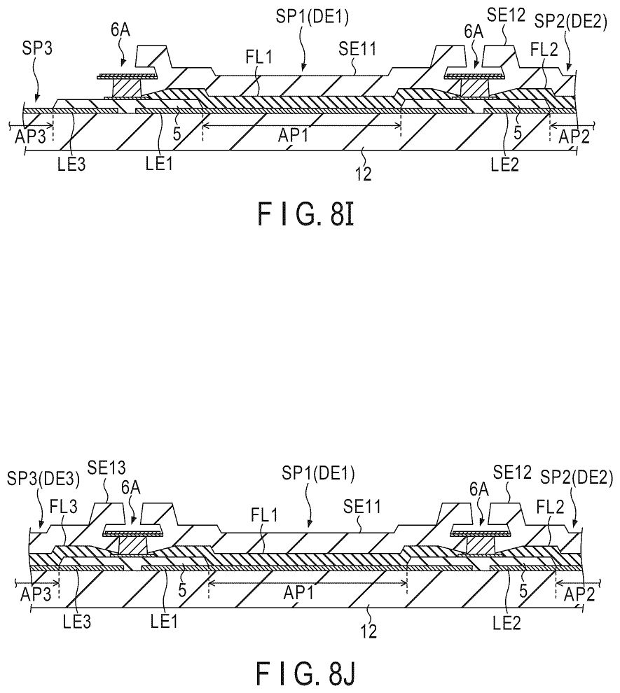

Next, an example of the method of manufacturing the display device DSP will be described. FIG. 7 is a flowchart showing an example of the method of manufacturing the display device DSP. Each of FIG. 8A to FIG. 8J is a schematic cross-sectional view showing a process of manufacturing the display device DSP. In FIG. 8A to FIG. 8J, attention is paid to the display area DA, and the elements located under the organic insulating layer 12 are omitted.

To form the panel portion PP, first, the circuit layer 11 which includes the inorganic insulating layers 31, 32, and 33, the organic insulating layer 34, a plurality of metal layers, and the semiconductor layer is formed above the substrate 10 of the motherboard MB (process PR1 in FIG. 7). In process PR1, the organic insulating layer 34 is formed in the surrounding area SA to form the dams DM3 to DM6.

Subsequently, the organic insulating layer 12 is formed (process PR2 in FIG. 7). In process PR2, the organic insulating layer 12 covering the organic insulating layer 34 is formed in the surrounding area SA. The dams DM3 to DM6 shown in FIG. 6A are thus formed in the surrounding area SA through processes PR2 and PR3. After process PR2, as shown in FIG. 8A, the lower electrodes LE1, LE2, and LE3 are formed on the organic insulating layer 12 (process PR3 in FIG. 7).

Subsequently, as shown in FIG. 8B, the rib layer 5 which covers the lower electrodes LE1, LE2, and LE3 is formed in the entire motherboard MB (process PR4 in FIG. 7). At this time, the pixel aperture AP1, AP2 or AP3 is not provided in the rib layer 5. The rib layer 5 can be formed by chemical vapor deposition (CVD).

After the formation of the rib layer 5, a process for forming the partitions 6A, 6B, and 6C is performed (process PR5 in FIG. 7). In process PR5, as shown in FIG. 8C, a first layer L1 which is processed to be the bottom layer 63, a second layer L2 which is processed to be the stem layer 64, a third layer L3 which is processed to be the first top layer 65, and a fourth layer L4 which is processed to be the second top layer 66 are formed in order in the entire motherboard MB.

Furthermore, a resist R1 is provided on the fourth layer L4. The resist R1 is patterned into the shape of the partitions 6A, 6B, and 6C. The first layer L1, the second layer L2, the third layer L3, and the fourth layer L4 are formed by, for example, sputtering.

After that, the first layer L1, the second layer L2, the third layer L3, and the fourth layer L4 are patterned using the resist R1 as a mask. In one example, the first layer L1 is formed of titanium nitride, the second layer L2 is formed of aluminum, the third layer L3 is formed of titanium, and the fourth layer L4 is formed of ITO. In this case, the patterning may include wet etching for removing a part of the fourth layer L4, which is exposed from the resist R1, dry etching for removing parts of the first, second, and third layers L1, L2, and L3, which are exposed from the resist R1, and wet etching for reducing the width of the second layer L2.

As shown in FIG. 8D, the partition 6A is formed in the display area DA through process PR5. In addition, the partitions 6B and 6C are formed in the surrounding area SA. After the formation of the partitions 6A, 6B, and 6C, the resist R1 is removed (peeled off).

Next, a process for providing the pixel apertures AP1, AP2, and AP3 is performed (process PR6 in FIG. 7). In process PR6, as shown in FIG. 8E, a resist R2 which covers the partition 6A is formed. Furthermore, dry etching for the rib layer 5 is performed using the resist R2 as a mask. As shown in FIG. 8F, the pixel apertures AP1, AP2, and AP3 through which the lower electrodes LE1, LE2, and LE3 are exposed are thereby formed in the rib layer 5. After the dry etching, the resist R2 is removed (peeled off). Incidentally, the pixel apertures AP1, AP2, and AP3 may be formed before the formation of the partitions 6A, 6B, and 6C.

After process PR6, a process for removing the rib layer 5 in the inspection pads TD shown in FIG. 5 is performed (process PR7 in FIG. 7). In process PR7, a resist which is open in the inspection pads TD is provided on the rib layer 5, and dry etching is performed for the rib layer 5.

After process PR7, a process for forming the display element DE1 is performed (process PR8 in FIG. 7). To form the display element DE1, first, the stacked film FL1 and the sealing layer SE11 are formed as shown in FIG. 8G. As shown in FIG. 3, the stacked film FL1 includes the organic layer OR1 which is in contact with the lower electrode LE1 through the pixel aperture AP1, the upper electrode UE1 which covers the organic layer OR1, and the cap layer CP1 which covers the upper electrode UE1. The organic layer OR1, the upper electrode UE1, and the cap layer CP1 can be formed by, for example, vapor deposition. In addition, the sealing layer SE11 can be formed by, for example, CVD.

The stacked film FL1 and the sealing layer SE11 are formed in the entire motherboard MB including the surrounding area SA and the margin area BA as well as the display area DA of each panel portion PP. The stacked film FL1 is divided into a plurality of parts by the partition 6A having an overhang shape. The sealing layer SE11 continuously covers each of the divided parts of the stacked film FL1, and the partition 6A.

Next, the stacked film FL1 and the sealing layer SE11 are patterned. In this patterning, a resist R3 is provided on the sealing layer SE11 as shown in 8G. The resist R3 covers the subpixel SP1 and a part of the partition 6A around the subpixel.

After that, an etching process using the resist R3 a mask is performed. As shown in FIG. 8H, the parts of the stacked film FL1 and the sealing layer SE11, which are exposed from the resist R3, are thereby removed. In other words, parts of the stacked film FL1 and the sealing layer SE11, which overlap the lower electrode LE1, remain and the other parts are removed. The display element DE1 is thereby formed in the subpixel SP1. For example, in the surrounding area SA and the margin area BA (shown in FIG. 4), the stacked film FL1 and the sealing layer SE11 are removed by this etching process. This etching process may include wet etching and dry etching processes which are performed in order for the sealing layer SE11, the cap layer CP1, the upper electrode UE1, and the organic layer OR1. After these etching processes, the resist R3 is removed (peeled off).

After process PR8, a process for forming the display element DE2 is performed (process PR9 in FIG. 7). The display element DE2 can be formed by a procedure similar to that of the display element DE1. In other words, when the display element DE2 is formed, the stacked film FL2 and the sealing layer SE12 are formed in the entire motherboard MB. As shown in FIG. 3, the stacked film FL2 includes the organic layer OR2 which is in contact with the lower electrode LE2 through the pixel aperture AP2, the upper electrode UE2 which covers the organic layer OR2, and the cap layer CP2 which covers the upper electrode UE2.

The organic layer OR2, the upper electrode UE2, and the cap layer CP2 can be formed by, for example, vapor deposition. In addition, the sealing layer SE12 can be formed by, for example, CVD. By patterning the stacked film FL2 and the sealing layer SE2, the display element DE2 is formed in the subpixel SP2 as shown in FIG. 8I. For example, in the surrounding area SA and the margin area BA, the stacked film FL2 and the sealing layer SE12 are removed by the etching during this patterning.

After process PR9, a process for forming the display element DE3 is performed (process PR10 in FIG. 7). The display element DE3 can be formed in a procedure similar to the procedures of the display elements DE1 and DE2. More specifically, when the display element DE3 is formed, the stacked film FL3 and the sealing layer SE13 are formed in the entire motherboard MB. As shown in FIG. 3, the stacked film FL3 includes the organic layer OR3 which is in contact with the lower electrode LE3 through the pixel aperture AP3, the upper electrode UE3 which covers the organic layer OR3, and the cap layer CP3 which covers the upper electrode UE3.

The organic layer OR3, the upper electrode UE3, and the cap layer CP3 can be formed by, for example, vapor deposition. In addition, the sealing layer SE13 can be formed by, for example, CVD. By patterning the stacked film FL3 and the sealing layer SE13, the display element DE3 is formed in subpixel SP3 as shown in FIG. 8J. For example, in the surrounding area SA and the margin area BA, the stacked film FL3 and the sealing layer SE13 are removed by the etching during the patterning.

Incidentally, it is assumed that the display elements DE1, DE2, and DE3 are formed in this order. However, the display elements DE1, DE2, and DE3 may be formed in the other orders.

The stacked films FL1, FL2, and FL3 formed by vapor deposition in processes PR8 to PR10 may have poor adherence to the base. For this reason, the stacked films FL1, FL2, and FL3 and the sealing layers SE11, SE12, and SE13 which cover these stacked films may be peeled off from the base when the display device DSP is manufactured.

The peeling easily occurs in a case where the stacked films FL1, FL2, and FL3 are continuously formed in a wide range. In the display area DA, the stacked films FL1, FL2, and FL3 are divided into pieces by the partition 6A. The peeling is therefore suspended.

In addition, in the present embodiment, the partitions 6B and 6C are provided in the surrounding area SA. Thus, the stacked films FL1, FL2, and FL3 are divided by the partitions 6B and 6C in the surrounding area SA as well, and the peeling is suspended.

After process PR10, the resin layer RS1 is formed (process PR11 in FIG. 7). The resin layer RS1 can be formed inside the dam structure DS1 by, for example, an ink-jet method. After process PR11, the sealing layer SE2 is formed in the entire mother substrate MB by, for example, CVD (process PR12 in FIG. 7).

After process PR12, etching for removing the rib layer 5 and the sealing layer SE2 which cover the terminal portion T is performed (process PR13 in FIG. 7). The etching is, for example, dry etching.

After process PR13, the resin layer RS2 is formed (process PR14 in FIG. 7). The resin layer RS2 can be formed inside the dam structure DS2 by, for example, an ink-jet method.

After process PR14, the polarizer 15 is formed on the resin layer RS2 (process PR15 in FIG. 7). After process PR15, the motherboard MB is cut along the cut line CL1 (process PR16 in FIG. 7).

After that, the inspection area TA is cut along the cut line CL2 after the inspection process using the inspection pads TD (process PR17 in FIG. 7). In process PR17, for example, the polarizer 15 is also cult along the cut line CL2.

The display device DSP is thereby completed. For the cutting in processes PR16 and PR17, for example, laser cutting for applying infrared laser beams along the cut lines CL1 and CL2 can be used. However, the cutting in processes PR16 and PR17 may be performed by the other methods such as scribe cutting.

Next, the area including the dam structure DS1, in the surrounding area SA, will be described.

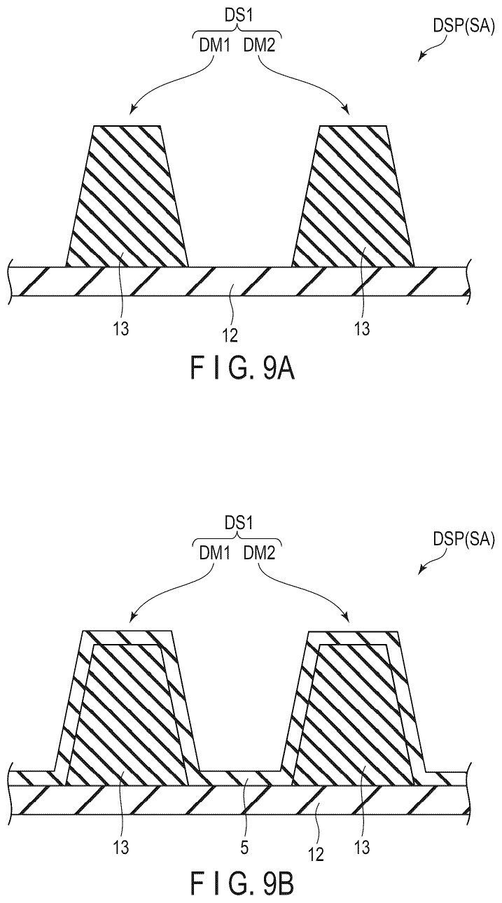

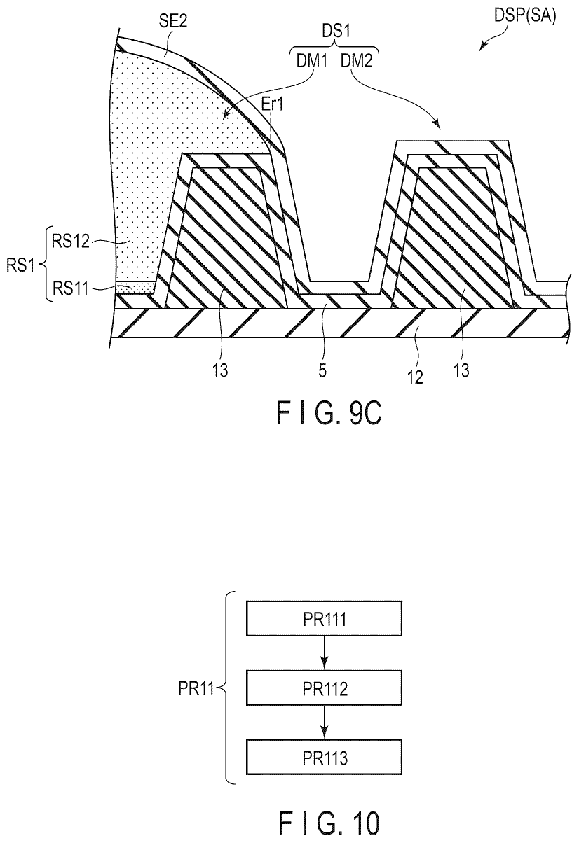

Each of FIG. 9A to FIG. 9C is a schematic cross-sectional view showing the process of manufacturing the display device DSP. In FIG. 9A to FIG. 9C, attention is paid mainly to the dams DM1 and DM2 of the dam structure DS1, and the elements located under the organic insulating layer 12 are omitted.

The method of manufacturing the display device DSP of the present embodiment further includes a process for forming the organic insulating layer 13 (process PR20 in FIG. 7). In other words, process PR20 corresponds to the process for forming the dams DM1 and DM2 of the dam structure DS1. In the present embodiment, process PR20 is performed after the organic insulating layer 12 is formed and before the lower electrodes LE1, LE2, and LE3 are formed.

More specifically, after process PR2, the organic insulating layer 13 is formed on the organic insulating layer 12 as shown in FIG. 9A. The organic insulating layer 13 is formed in a predetermined shape by, for example, photolithography.

The dams DM1 and DM2 (dam structure DS1) for damming the resin layer RS1 to be cured are thereby formed on the organic insulating layer 12. In addition, as shown in FIG. 6A, the organic insulating layer 13 covers the organic insulating layer 12 at the dams DM3 to DM6.

Subsequently, in process PR4 of FIG. 7, each of the dams DM1 and DM2 is covered with the rib layer 5 as shown in FIG. 9B. The organic insulating layer 13 is located between the organic insulating layer 12 and the rib layer 5. In other words, the dams DM1 and DM2 are not exposed from the rib layer 5.

After that, the resin layer RS1 is formed inside the dam structure DS1 (process PR11 in FIG. 7) and, as shown in FIG. 9C, the resin layer RS1 and the rib layer 5 are covered with the sealing layer SE2 (process PR12 in FIG. 7), through the processes from process PR4 to process PR10.

An example of process PR11 for forming the resin layer RS1 will be described.

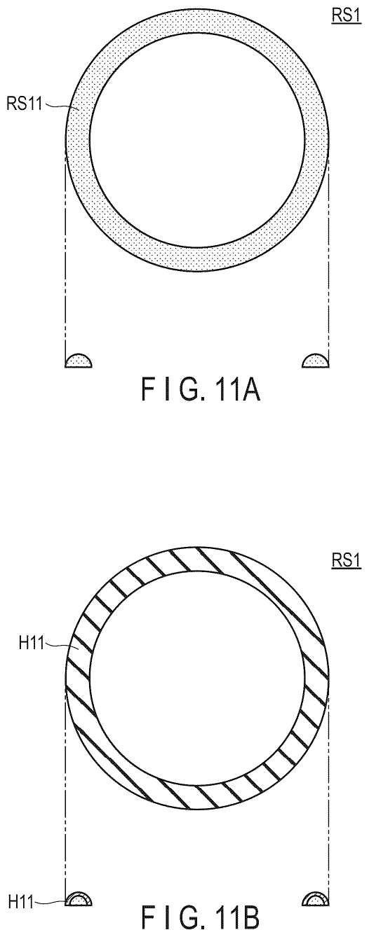

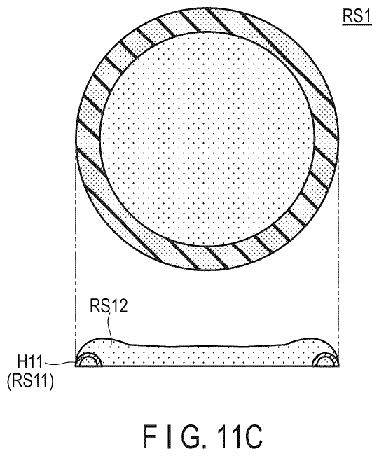

FIG. 10 is a flowchart showing an example of the process for manufacturing the resin layer RS1. FIG. 11A to FIG. 11C are diagrams illustrating the process for manufacturing the resin layer RS1.

Process PR11 includes a plurality of coating processes for forming the resin layer RS1. First, as shown in FIG. 11A, a material is applied on an outer surrounding area of the area where the resin layer RS1 is to be formed (process PR111 in FIG. 10). In FIG. 11A, a layer formed in process PR111 is shown as the resin layer RS11. Incidentally, a width of the resin layer RS11 is varied as appropriate.

After that, the resin layer RS11 is cured by, for example, UV irradiation (process PR112 in FIG. 10). In process PR112, for example, only the surface of the resin layer RS11 is cured. In FIG. 11B, the cured part is shown as a layer H11.

Next, a material is further applied over the entire area where the resin layer RS1 is formed (process PR113 in FIG. 10). In FIG. 11C, the layer formed in process PR113 is shown as a resin layer RS12.

Then, the resin layers RS11 and RS12 are cured in process PR113. Thus, the resin layer RS1 includes a plurality of layers (resin layer RS11 and resin layer RS12). Incidentally, process PR113 may include a plurality of coating processes.

A part of the resin layer RS12 is formed on the layer H11 of the resin layer RS11. The layer H11 has different surface wettability compared to the resin layer RS11 to be cured. More specifically, the layer H11 more readily exerts surface tension on the resin layer RS12 to be cured, which is applied on the layer H11, compared to uncured resin layer RS11.

As a result, the resin layer RS12 to be cured is less likely to overflow outward compared to the resin layer RS11, during process PR113. Furthermore, in the present embodiment, since the resin layer RS1 to be cured is dammed by the dam structure DS1, the spread of resin layer RS1 is further suppressed.

According to the display device DSP configured in the same manner as the present embodiment, the display quality can be improved. In the present embodiment, the dams DM1 and DM2 of the dam structure DS1 are provided above the organic insulating layer 12.

As a comparative example, it is assumed that the dams DM1 and DM2 are formed at the same position as the dam DM3. More specifically, it is assumed that the dams DM1 and DM2 are provided above the circuit layer 11 (inorganic insulating layer 33). An upper surface of the resin layer RS1 in the comparative example is shown as a surface S100 with dashed lines in FIG. 6B.

In the comparative example, the thickness of the resin layer RS1 changes abruptly at an end portion WP (shown in FIG. 6B). The end portion WP refers to the area of the vicinity including an edge of the display area DA and its vicinity. For example, the end portion WP is the area extending from the apex of the resin layer RS1 to the edge of the display area DA.

The abrupt change in thickness of the resin layer RS1 at the end portion WP may cause degradation in display quality. In FIG. 6B, a difference in the Z-directional position between the apex of the resin layer RS1 and the surface S100 of the resin layer RS1 at the edge of the display area DA, in the comparative example, is shown as difference H1. Particularly, when the width from the display area DA to the cut line CL2 (frame portion) becomes small, it becomes difficult to sufficiently ensure the thickness of the resin layer RS1 provided in the surrounding area SA. This width is, for example, 0.7 to 1 mm.

For this reason, the difference H1 increases, making the thickness of the resin layer RS1 change abruptly, at the end portion WP. Such an abrupt change in thickness can cause luminance at the end portion WP to change. For this reason, a brightness difference may occur between the end portion WP and the central part of the display area DA, and the display quality of the display device may be degraded. For example, a frame-like brightness unevenness may occur in the display area DA.

In contrast, in the present embodiment, the dams DM1 and DM2 are provided on the organic insulating layer 12 as described above. In other words, the dams DM1 and DM2 can be provided at higher positions, compared to a case where the dams DM1 and DM2 are provided on the circuit layer 11. As a result, the dams DM1 and DM2 can dam the resin layer RS1 at higher positions higher than those in the comparative example.

Consequently, the thickness of the resin layer RS1 is less likely to change abruptly at the end portion WP as shown in FIG. 6B. A difference in the Z-directional position between the apex of the resin layer RS1 and the surface S10 of the resin layer RS1 at the edge of the display area DA in the present embodiment is shown as difference H2.

In the present embodiment, the change in thickness at the end portion WP is smaller than that in the comparative example. More specifically, the difference H2 is smaller than the difference H1 (difference H1>difference H2). In the present embodiment, the thickness of the resin layer RS1 can easily be controlled.

As a result, a luminance difference is less likely to occur between the end portion WP and the central part of the display area DA, and the decrease in display quality can be suppressed. In the present embodiment, particularly, the display quality can be improved in the display device DSP with a narrow frame. In addition, by providing the resin layer RS1 at a high position, the amount of application of the resin layer RS1 can be increased compared to the comparative example. The difference H2 of the resin layer RS1 can be thereby further suppressed.

Various desirable effects can be obtained from the present embodiment in addition to the effects described here.

Next, other embodiments will be described. Incidentally, in the other embodiments described below, the same components as those of the above-described first embodiment may be denoted by the same reference numerals as those in the first embodiment, and their detailed description may be omitted or simplified. Regarding the display device DSP, the mother substrate MB, and the panel portion PP, configurations similar to those of the first embodiment can be applied to configurations which are not particularly referred to.

### Second Embodiment

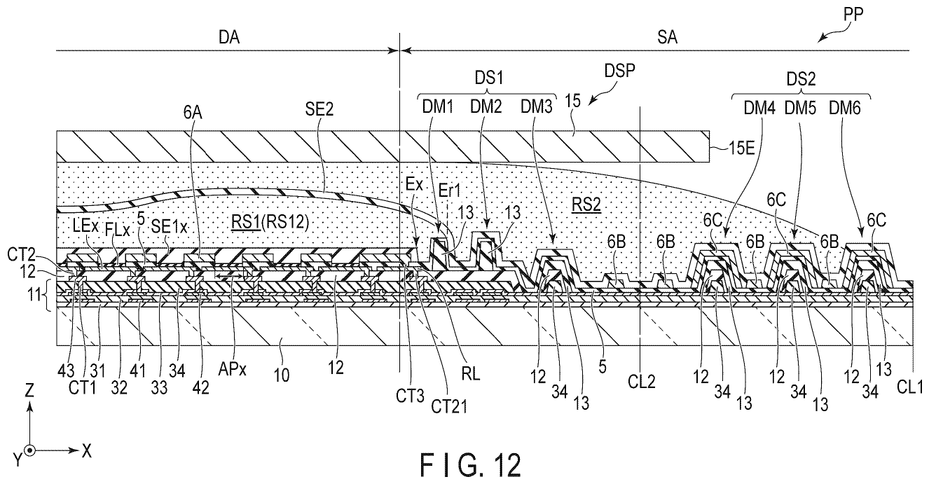

FIG. 12 is a schematic cross-sectional view showing a panel portion PP according to the present embodiment. The present embodiment is different from the first embodiment in configuration of the resin layer RS1. More specifically, the resin layer RS1 does not include the resin layer RS11 shown in FIG. 7. The resin layer RS1 is composed of a resin layer RS12. From another viewpoint, the thickness of the resin layer RS1 in the present embodiment is smaller than that of the resin layer RS1 in the first embodiment. In this case, the height HR of the resin layer RS1 is also smaller than that in the first embodiment.

When focusing on the manufacturing processes, process PR11 in the present embodiment do not include processes PR111 and PR112 shown in FIG. 10. When the thickness of the resin layer RS1 is smaller than or equal to a predetermined value, the resin layer RS11 may not be formed in advance.

For example, when the area of the apertures in the partition 6A is large, in the display area DA, the resin layer RS1 to be cured may easily flow into each aperture, and the thickness of the resin layer RS1 can be made smaller. In other words, when the area of the apertures in the partition 6A is large, the resin layer RS1 to be cured is less likely to flow into the apertures, i.e. so-called coating skip is less likely to occur.

Incidentally, the thickness of the resin layer RS1 can be changed as appropriate based on a size of a foreign matter tolerable in the manufacturing process. More specifically, by making the thickness of the resin layer RS1 greater than the size of the foreign matter, damage to a sealing layer SE2 by the foreign matter is suppressed.

The same advantages as those of the first embodiment can also be obtained in the present embodiment. In the present embodiment, the height of the dams can be made smaller by making the thickness of the resin layer RS1 smaller. In addition, in the manufacturing processes, processes PR111 and PR112 in process PR20 can be omitted.

Incidentally, the first and second embodiments have disclosed the example of forming the dams DM1 and DM2 by the organic insulating layer 13, but the dams DM1 and DM2 may also be formed by the organic insulating layer 12. In this case, the organic insulating layer 12 and the dams DM1 and DM2 are formed integrally. For example, the dams DM1 and DM2 may be formed by applying a halftone mask when forming the organic insulating layer 12 in process PR1 instead of process PR20.

Next, third to seventh embodiments will be described. The third to seventh embodiments are different from each of the above-described embodiment in the process for forming the organic insulating layer 13 and the arrangement of the dams DM1 and DM2.

### Third Embodiment

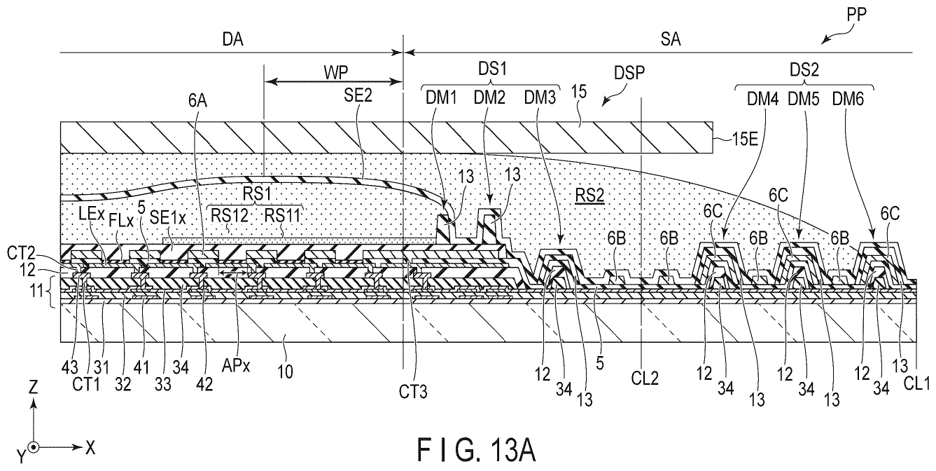

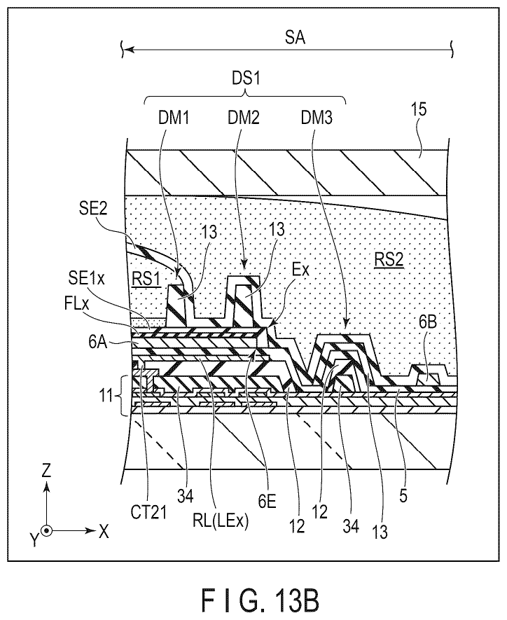

FIG. 13A is a schematic cross-sectional view showing a panel portion PP according to the present embodiment. FIG. 13B is an enlarged view showing a vicinity of dams DM1 and DM2 in FIG. 13A. In the present embodiment, a lower electrode LeX and a partition 6A are continuously provided from a display area DA to a surrounding area SA.

Dams DM1 and DM2 are provided above the partition 6A as shown in FIG. 13A and FIG. 13B. In the present embodiment, a sealing layer SE1x is located between the partition 6A and the dams DM1 and DM2. An organic insulating layer 13 is in contact with the sealing layer SE1x. Furthermore, a stacked film FLx may be further provided between the partition 6A and the sealing layer SE1x as shown in FIG. 13B.

An organic insulating layer 34, an organic insulating layer 12, a lower electrode LEx (relay layer RL), a rib layer 5, a partition 6A, the stacked film FLx, and the sealing layer SE1x are stacked in this order, under the dams DM1 and DM2.

In the example of FIG. 13A and FIG. 13B, the dam DM1 is in contact with both a resin layer RS11 and a resin layer RS12. The resin layer RS1 is surrounded by the sealing layer SE1x, the dam DM1 (organic insulating layer 13), and the sealing layer SE2. Impregnation of moisture into the resin layer RS1 is thereby suspended.

An end portion Ex of the sealing layer SE1x is located on a cut line CL2 side relative to the dams DM1 and DM2, as shown in FIG. 13B. The end portion Ex of the sealing layer SE1x covers an end portion 6E (first end portion) of the partition 6A. The end portion 6E is located above the rib layer 5. The sealing layer SE2 covers the end portion Ex of the sealing layer SE1x. Furthermore, the sealing layer SE2 covers a dam DM3 and partitions 6B and 6C as shown in FIG. 13A.

When focusing on the dam DM3, the rib layer 5, the organic insulating layer 13, and the sealing layer SE2 are stacked in this order on the dam DM3. In addition, when focusing on dams DM4 to DM6, the rib layer 5, a partition 6C, the organic insulating layer 13, and the sealing layer SE2 are stacked in this order on the dams DM4 to DM6.

Next, arrangement of the dams DM1 and DM2 relative to the partition 6A in plan view will be described.

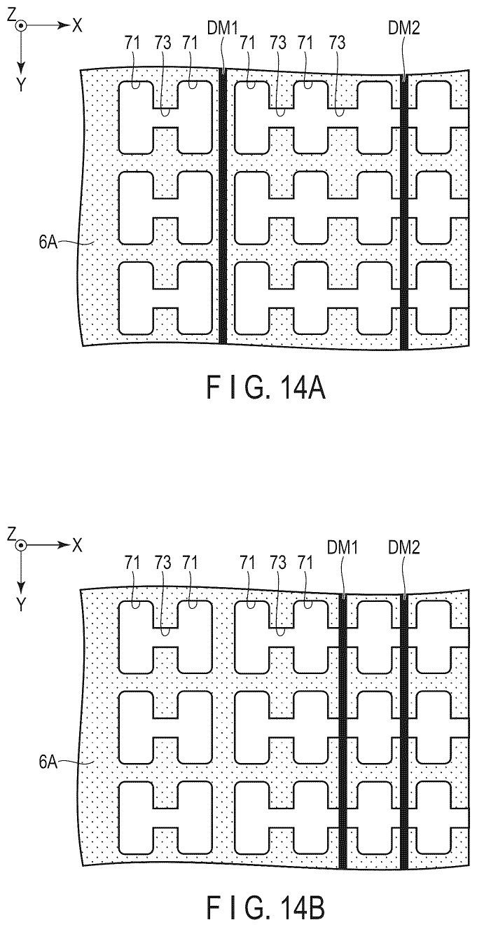

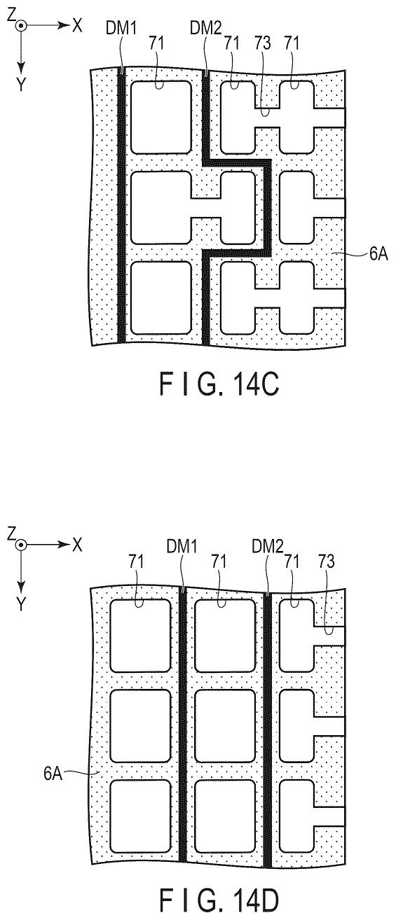

FIG. 14A to FIG. 14D are diagrams illustrating examples of the arrangement of the dams DM1 and DM2. In FIG. 14A to FIG. 14D, the partition 6A and the dams DM1 and DM2 are shown and the other elements are omitted. In FIG. 14A to FIG. 14D, the partition 6A is marked with dots.

The partition 6A has a plurality of apertures 71 (partition apertures) in the peripheral region SA. The apertures 71 are provided in matrix in the X-direction and the Y-direction. For example, the apertures 71 have a shape elongated in the Y-direction.

The partition 6A may further include slits 73. The apertures 71 adjacent in the X-direction may be connected via the slits 73. Two or more apertures 71 are connected via the slits 73. Furthermore, the apertures 71 may be different from each other in X-directional width as shown in FIG. 14A to FIG. 14D. Incidentally, the X-directional width and the Y-directional width of the apertures 71 may be changed as appropriate. The shape of the apertures 71 is not limited to the illustrated example.

In the example of FIG. 14A to FIG. 14D, the dams DM1 and DM2 extend in the Y-direction. The dams DM1 and DM2 are provided between the apertures 71 adjacent to each other in the X-direction. In the example of FIG. 14A, the dam DM1 does not overlap with the slits 73, but the dam DM2 overlaps with the slits 73. In other words, the dam DM2 intersects the slits 73. In contrast, both the dams DM1 and DM2 may overlap with the slits 73 as shown in the example of FIG. 14B.

In addition, neither the dam DM1 nor the DM2 may overlap with the slits 73 as shown in the examples of FIG. 14C and FIG. 14D. Furthermore, the dam DM2 may be formed in a zigzag shape as shown in the example of FIG. 14C. More specifically, the dam DM2 may include parts extending in the X-direction and parts extending in the Y-direction.

FIG. 14A has disclosed the example in which the dam DM2 overlaps with the slits 73, but the dam DM1 may overlap with the slits 73 while the dam DM2 may not overlap with the slits 73. FIG. 14C has disclosed the example in which the dam DM2 is formed in a zigzag shape, but the dam DM1 may be formed in a zigzag shape or both the dams DM1 and DM2 may be formed in a zigzag shape. In addition, at least one of the dams DM1 and DM2 may overlap with the apertures 71. As described above, various arrangement patterns can be applied to the dams DM1 and DM2 depending on the shape, position, and the like of the apertures 71 in the partition 6A.

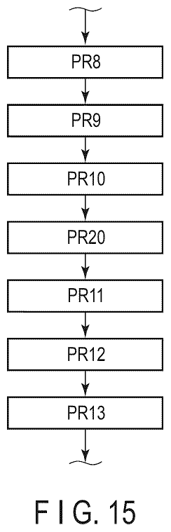

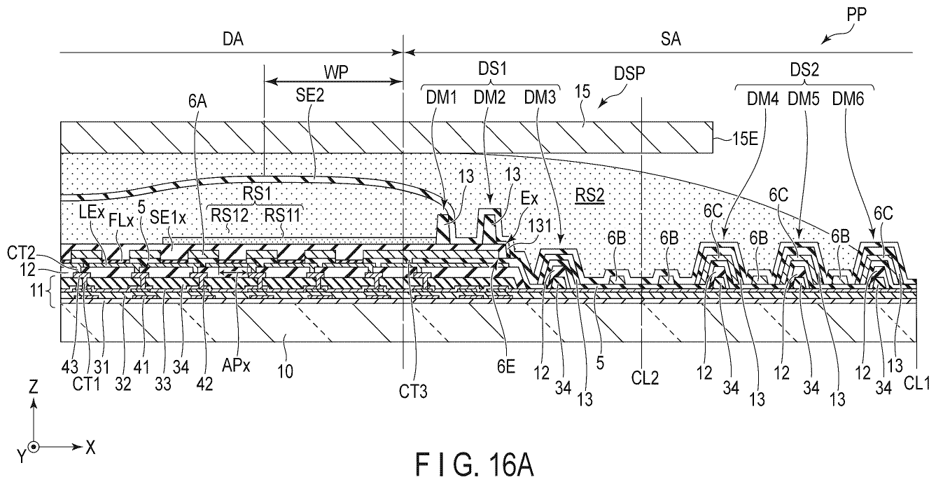

Next, an example of processes of manufacturing the display device DSP according to the present embodiment will be described. FIG. 15 is a flowchart showing an example of a method of manufacturing the display device DSP. Parts of the manufacturing processes are shown in FIG. 15.

In the present embodiment, process PR20 is performed after the process for forming the display element DE3 (process PR10 in FIG. 15) and before the process for forming the resin layer RS1 (process PR11 in FIG. 15). The dams DM1 and DM2 (dam structure DS1) to dam the resin layer RS1 to be cured are thereby formed above the partition 6A. More specifically, the dams DM1 and DM2 are formed on the sealing layer SE1x.

Process PR20 may include a process for baking the organic insulating layer 13. The moisture that may be contained in the organic insulating layer 13 is removed in this process. In the present embodiment, the resin layer RS1 is in contact with the dam DM1 (organic insulating layer 13). As a result, impregnation of moisture into the resin layer RS1 can be further suspended by sufficiently removing moisture that may be contained in the organic insulating layer 13. As a result, the reliability of the display device DSP can be improved.

The same advantages as those of the first embodiment can also be obtained in the present embodiment. In the present embodiment, the dams DM1 and DM2 are provided on the sealing layer SE1x. As a result, the position of the dams DM1 and DM2 (for example, the distance from the upper surface of the substrate 10 to the bottom surfaces of the dams DM1 and DM2) can be raised compared to the first embodiment.

In other words, according to the present embodiment, the position of dams DM1 and DM2 can be raised without increasing the load on manufacturing processes. As a result, when the amount of the material applied to form the resin layer RS1 is the same, the difference H2 (shown in FIG. 6B) can be made smaller than that in the first embodiment. Furthermore, in the present embodiment, compared to the first embodiment, since the area where the partition 6A is formed is expanded, peeling of the laminated film FLx to be formed in subsequent processes can be further suspended.

Incidentally, in the present embodiment as well, parts of metal layers 41 and 42 (circuits formed by the metal layers 41 and 42) of the circuit layer 11 may be provided under the dams DM1 and DM2.

### Fourth Embodiment

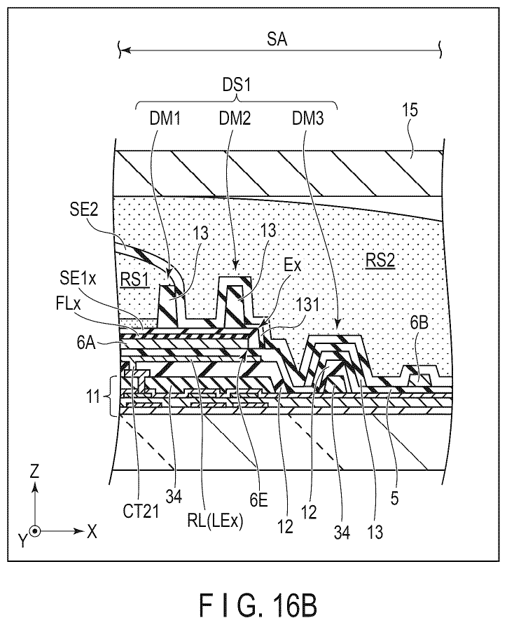

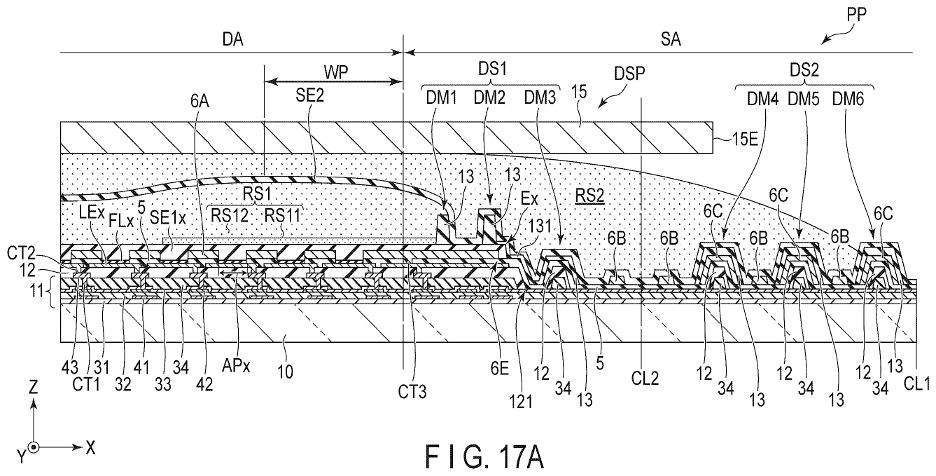

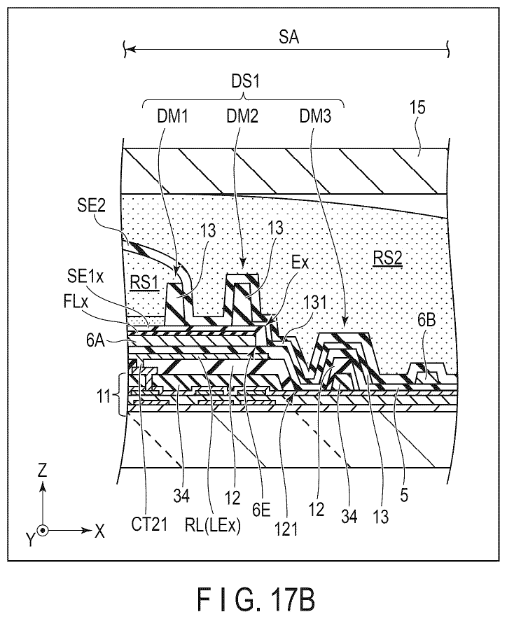

FIG. 16A is a schematic cross-sectional view showing a panel portion PP according to the present embodiment. FIG. 16B is an enlarged view showing a vicinity of the dams DM1 and DM2 in FIG. 16A. FIG. 17A is a schematic cross-sectional view showing the panel portion PP according to the present embodiment. FIG. 17B is an enlarged view showing the vicinity of the dams DM1 and DM2 in FIG. 17A.

In the present embodiment, a dam structure DS1 is different from the dam structure DS1 in the third embodiment. More specifically, the shape of the dam DM2 is different from the shape of the dam DM2 in the third embodiment.

The dam DM2 includes an extending portion 131 as shown in FIG. 16A and FIG. 17A. The extending portion 131 extends to a cut line CL2 side relative to the dam DM2. The extending portion 131 has a thickness smaller than the other parts of the dam DM2. In the example of FIG. 16B, the extending portion 131 covers an end portion Ex of a sealing layer SE1x.

The extending portion 131 may further extend toward the cut line CL2 as shown in the example of FIG. 17B. More specifically, the extending portion 131 further covers an end portion 121 (third end portion) of an organic insulating layer 12 via a rib layer 5. The end portion 121 is located outward from the end portion Ex of the sealing layer SE1x. In this case, the extending portion 131 is in contact with the rib layer 5 between the end portion 121 and a dam DM3.

In addition, in the example of FIG. 17, the extending portion 131 is connected to the organic insulating layer 13 covering the dam DM3. In other words, a part of the organic insulating layer 13 forming the dam DM2 covers the dam DM3.

In the present embodiment, process PR20 includes a process for forming the extending portion 131. For example, the extending portion 131 is formed in step PR20 of FIG. 15 by, for example, applying a halftone mask.

The same advantages as those of the third embodiment can also be obtained in the present embodiment. In the present embodiment, the dam DM2 includes the extending portion 131. By covering an end portion Ex with the protruding portion 131, the step at the end portion Ex can be made smaller. From the other viewpoint, an angle of inclination based on the step can be made smaller.

As a result, inconveniences that cracks may occur in the sealing layer SE2 provided above the end portion Ex, lines (for example, lines for a touch panel) provided on the sealing layer SE2 may be broken when crossing over the end portion Ex, and the like are less likely to occur. As a result, the reliability of the display device DSP can be improved.

Furthermore, in the example of FIG. 17B, the extending portion 131 is provided above the end portion 121 of the organic insulating layer 12. As a result, the step at the end portion 121 can be made smaller. Consequently, the inconveniences are less likely to occur.

Incidentally, the example of FIG. 17B has disclosed the example in which the extending portion 131 is connected to the organic insulating layer 13 covering the dam DM3, but the extending portion 131 may not be connected to the organic insulating layer 13 covering the dam DM3. Furthermore, the present embodiment has disclosed the example in which the dam DM2 includes the extending portion 131 but, if the only dam DM1 is provided above the sealing layer SE1x, the dam DM1 may also include the extending portion 131.

### Fifth Embodiment

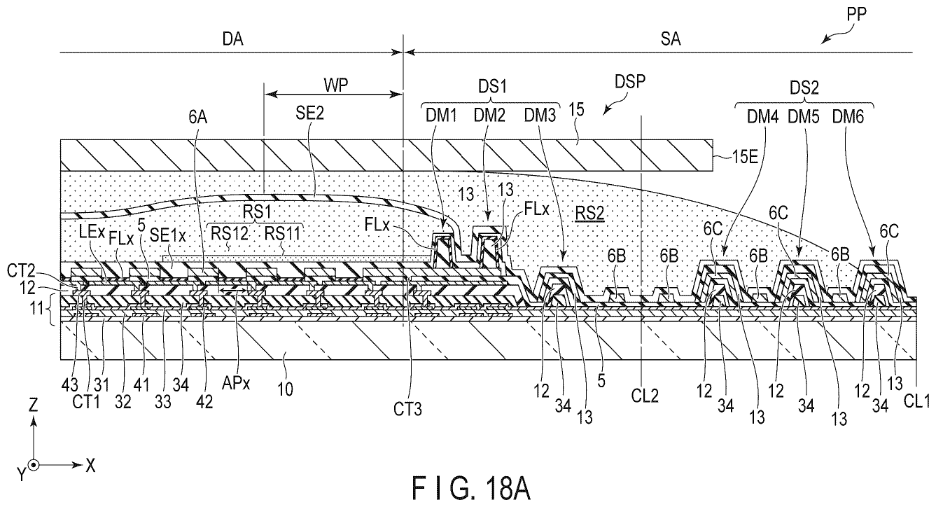

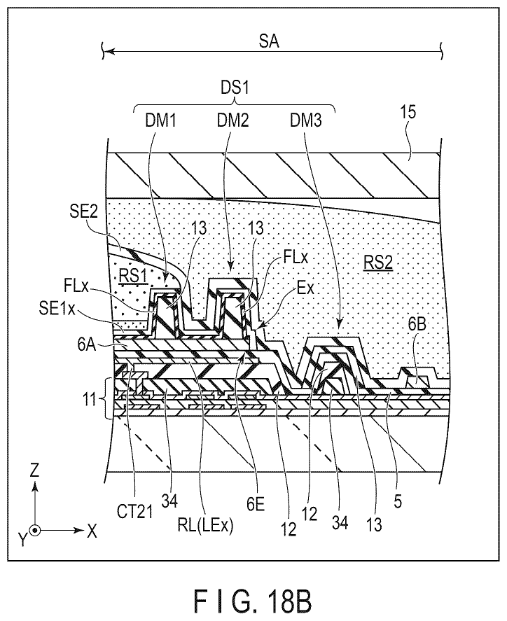

FIG. 18A is a schematic cross-sectional view showing a panel portion PP according to the present embodiment. FIG. 18B is an enlarged view showing a vicinity of dams DM1 and DM2 in FIG. 18A. In the present embodiment, the dams DM1 and DM2 are provided on a partition 6A as shown in FIG. 18A and FIG. 18B. More specifically, the dams DM1 and DM2 are in contact with the second top layer 66 (shown in FIG. 3) of the upper portion 62 of the partition 6A.

An organic insulating layer 34, an organic insulating layer 12, a lower electrode LEx (relay layer RL), a rib layer 5, and the partition 6A are stacked in this order, under the dams DM1 and DM2. A stacked film FLx and a sealing layer SE1x are stacked in this order above the dams DM1 and DM2. As described above, the stacked film FLx includes an organic layer including a light emitting layer, an upper electrode, and a cap layer.

In the example of FIG. 18A, a resin layer RS1 is surrounded by a sealing layer SE1x and a sealing layer SE2. Impregnation of moisture into the resin layer RS1 is thereby suspended. Furthermore, since the dam DM1 is covered with the sealing layer SE1x, impregnation of moisture that may be contained in an organic insulating layer 13 is suppressed.

As shown in FIG. 18B, an end portion Ex of the sealing layer SE1x is located on a cut line CL2 side relative to the dams DM1 and DM2 and covers an end portion of the partition 6A. The sealing layer SE2 covers the end portion Ex of the sealing layer SE1x. The sealing layer SE2 is in contact with the rib layer 5 in an area located in an outer side relative to the end portion Ex. More specifically, the sealing layer SE2 covers a dams DM3, and partitions 6B and 6C.

When focusing on the dam DM3, the rib layer 5, the organic insulating layer 13, and the sealing layer SE2 are stacked in this order on the dam DM3. In addition, when focusing on dams DM4 to DM6, the rib layer 5, a partition 6C, the organic insulating layer 13, and the sealing layer SE2 are stacked in this order on the dams DM4 to DM6.

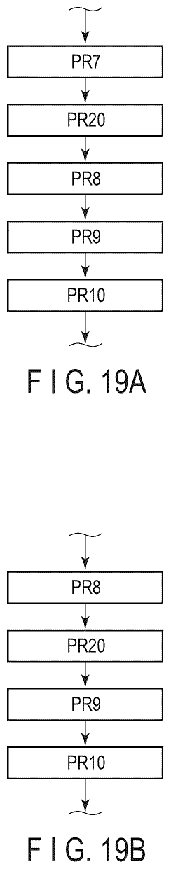

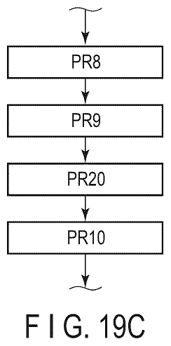

Next, an example of processes of manufacturing the display device DSP according to the present embodiment will be described. FIG. 19A to FIG. 19C are flowcharts showing an example of the method of manufacturing the display device DSP. FIG. 19A to FIG. 19C show parts of the manufacturing processes. In the present embodiment, process PR20 is performed before the process for forming the display element DE3 (process PR10 in FIG. 15).

In the example of FIG. 19A, this process is performed after process PR7 and before process PR8. In the example of FIG. 19B, this process is performed after process PR8 and before process PR9. In the example of FIG. 19C, this process is performed after process PR9 and before process PR10. The dams DM1 and DM2 (dam structure DS1) are thereby formed on the partition 6A. In addition, the stacked film FLx and the sealing layer SE1x are stacked on the dams DM1 and DM2.

The same advantages as those of the first embodiment can also be obtained in the present embodiment. In the present embodiment, the dams DM1 and DM2 are provided on the partition 6A. As a result, the position of the dams DM1 and DM2 (for example, the distance from the upper surface of the substrate 10 to the bottom surfaces of the dams DM1 and DM2) can be raised compared to the first embodiment.

In addition, in the present embodiment, compared to the first embodiment, since the area where the partition 6A is formed is further expanded, peeling of the laminated film FLx to be formed in subsequent processes can be further suspended.

Furthermore, in the present embodiment, the dams DM1 and DM2 are covered with the sealing layer SE1x. According to the present embodiment, impregnation of the moisture that may be contained in the organic insulating layer 13, into the resin layer RS1, can be suppressed by the sealing layer SE1x. As a result, the reliability of the display device DSP can be improved.

### Sixth Embodiment

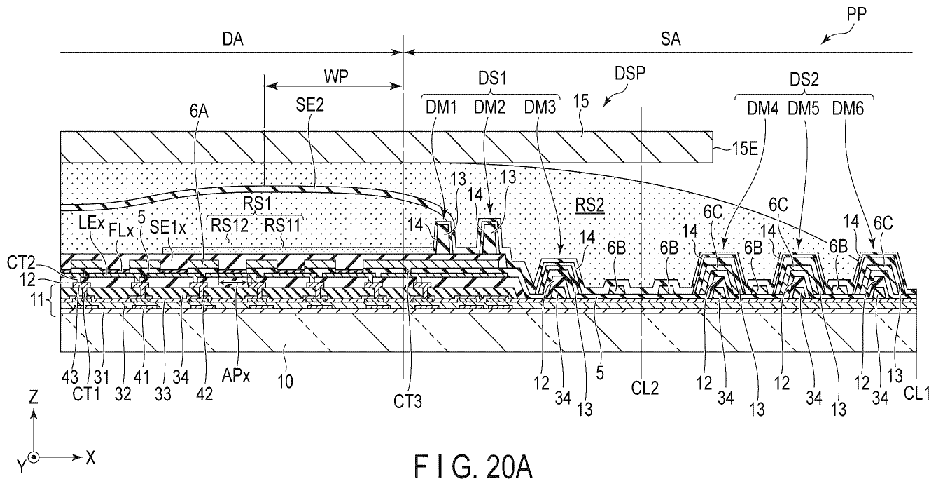

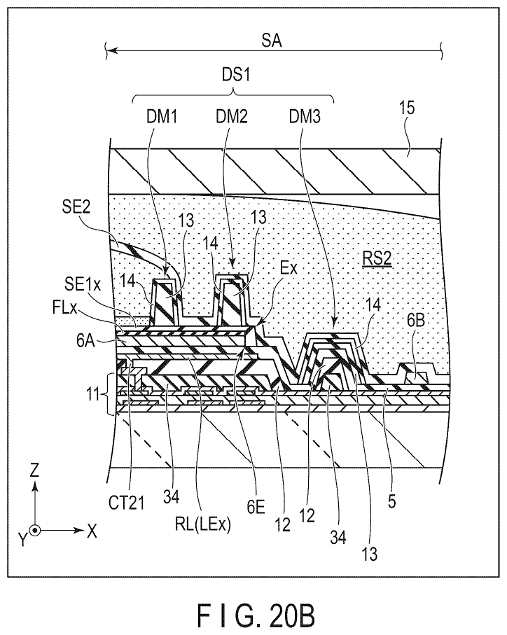

FIG. 20A is a schematic cross-sectional view showing a panel portion PP according to the present embodiment. FIG. 20B is an enlarged view showing a vicinity of dams DM1 and DM2 in FIG. 20A. The present embodiment is different from the third embodiment in that the panel portion PP (display device DSP) further comprises a sealing layer 14 (third sealing layer).

The sealing layer 14 is formed of an inorganic insulating material such as silicon nitride (SiNx), silicon oxide (SiOx) or silicon oxynitride (SiON). In one example, the sealing layer 14 is formed of silicon nitride.

The sealing layer 14 is provided in each of the dam structures DS1 and DS2. More specifically, the sealing layer 14 covers each of dams DM1 to DM6. The dams DM1 and DM2 are further covered with a sealing layer SE2. In other words, the sealing layer SE2 overlaps with the sealing layer 14.

When focusing on the dam DM3, the rib layer 5, the organic insulating layer 13, the sealing layer 14, and the sealing layer SE2 are stacked in this order on the dam DM3. In addition, when focusing on the dams DM4 to DM6, the rib layer 5, a partition 6C, the organic insulating layer 13, the sealing layer 14, and the sealing layer SE2 are stacked in this order on the dams DM4 to DM6. In other words, the sealing layer 14 is also provided outside the dam structure DS1 in the surrounding area SA.

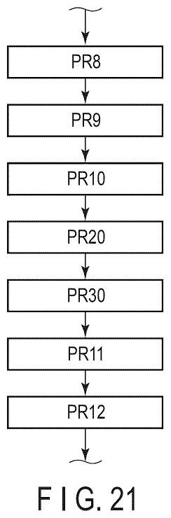

Next, an example of processes of manufacturing the display device DSP according to the present embodiment will be described. FIG. 21 is a flowchart showing an example of a method of manufacturing the display device DSP. Parts of the manufacturing processes are shown in FIG. 21.

The method of manufacturing the display device DSP of the present embodiment further includes a process for forming the sealing layer 14 (process PR30 in FIG. 21). Process PR30 is performed, for example, after a process for forming the organic insulating layer 13 (process PR20) and before a process for forming the resin layer RS1 (process PR11). In process PR30, after the sealing layer 14 is formed over the display area DA and the surrounding area SA, the sealing layer 14 is patterned to cover the dams DM1 to DM6.

The same advantages as those of the third embodiment can also be obtained in the present embodiment. In the present embodiment, the dams DM1 and DM2 are covered with the sealing layer 14. According to the present embodiment, impregnation of the moisture that may be contained in the organic insulating layer 13, into the sealing layer 14, is suppressed by the sealing layer SE1x. As a result, the reliability of the display device DSP can be improved.

### Seventh Embodiment

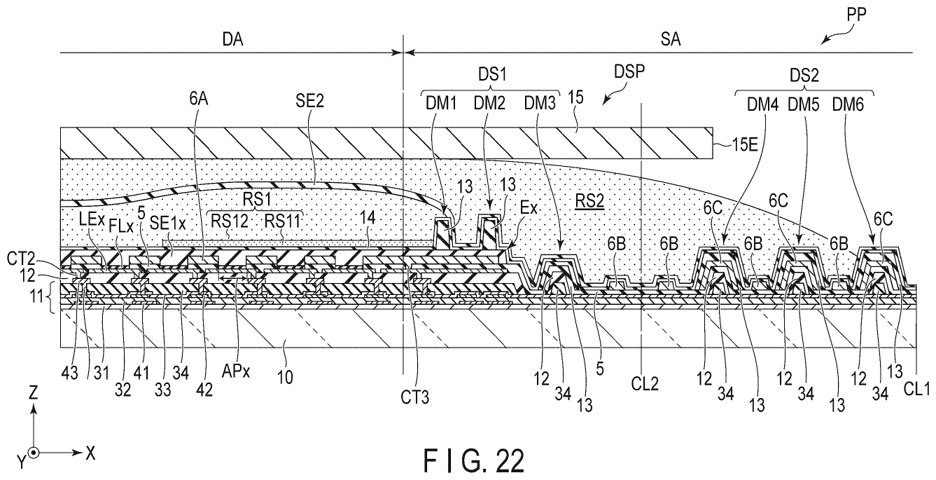

FIG. 22 is a schematic cross-sectional view showing a panel portion PP according to the present embodiment. The present embodiment is different from the sixth embodiment in arrangement of the sealing layers 14. More specifically, the sealing layer 14 is provided over a display area DA and a surrounding area SA. In the present embodiment, process PR30 (shown in FIG. 21) does not include a process for patterning the sealing layer 14.

When focusing on the display area DA, the sealing layer 14 is provided between a sealing layer SE1x and a resin layer RS1. When focusing on a partition 6B, the sealing layer 14 and a sealing layer SE2 are stacked in that order on the partition 6B. In addition, the sealing layer 14 is provided to cover an end portion Ex of the sealing layer SE1x, and the like.

The same advantages as those of the sixth embodiment can also be obtained in the present embodiment.

According to the display device DSP of each of the embodiments configured as described above, the display quality can be improved. In addition, various desirable effects can be obtained from each of the above-described embodiments.

Each of the above-described embodiments has disclosed the example in which the dam structure DS1 includes the dams DM1 to DM3, but the dam structure DS1 needs only to include the dam DM1 and may not include at least one of the dams DM2 and DM3. The embodiments have disclosed the examples in which the dam structure DS2 includes the dams DM4 to DM6, but the dam structure DS2 needs only to include the dam DM6 and may not include at least one of the dams DM4 and DM5.

All of display devices that can be implemented by a person of ordinary skill in the art through arbitrary design changes to the display devices described above as embodiments of the present invention come within the scope of the present invention as long as they are in keeping with the spirit of the present invention. Various types of the modified examples are easily conceivable within the category of the ideas of the present invention by a person of ordinary skill in the art and the modified examples are also considered to fall within the scope of the present invention. For example, the above embodiments with addition, deletion, and/or designed change of their structural elements by a person having ordinary skill in the art, or the above embodiments with addition, omission, and/or condition change of their processes by a person having ordinary skill in the art are encompassed by the scope of the present inventions without departing the spirit of the inventions.

In addition, the other advantages of the aspects described in the embodiments, which are obvious from the descriptions of the present specification or which can be arbitrarily conceived by a person of ordinary skill in the art, are considered to be achievable by the present invention as a matter of course.

Examples of the method of manufacturing the display device as obtained from the configuration disclosed herein is appended below.

### Note 1

A display device manufacturing method including:
forming an organic insulating layer over a display area and a surrounding area above a substrate including the display area and the surrounding area surrounding the display area;
forming a dam structure above the organic insulating layer in the surrounding area;
forming a plurality of lower electrodes above the organic insulating layer in the display area;
forming an inorganic insulating layer including a plurality of pixel apertures overlapping with the plurality of lower electrodes, respectively, to cover the dam structure;
forming a first partition including a first conductive lower portion provided above the inorganic insulating layer, and a first upper portion having an end portion protruding from a side surface of the first lower portion, and surrounding each of the plurality of pixel apertures;
forming a plurality of stacked films each including an organic layer which covers the lower electrode through the pixel aperture and which emits light in accordance with
application of a voltage; forming a first sealing layer formed of an inorganic insulating material to cover the plurality of stacked films; and
forming a first resin layer provided inside the dam structure and covering the first sealing layer.

### Note 2

The display device manufacturing method of note 1, further including:
forming a second sealing layer formed of an inorganic material to cover the first resin layer, wherein
the second sealing layer is in contact with the inorganic insulating layer in an area outside the first resin layer.

### Note 3

A display device manufacturing method including:
forming an organic insulating layer over a display area and a surrounding area above a substrate including the display area and the surrounding area surrounding the display area;
forming a plurality of lower electrodes above the organic insulating layer in the display area;
forming an inorganic insulating layer including a plurality of pixel apertures overlapping with the plurality of lower electrodes, respectively;
forming a first partition including a first conductive lower portion provided above the inorganic insulating layer, and a first upper portion having an end portion protruding from a side surface of the first lower portion, surrounding each of the plurality of pixel apertures in the display area, and provided from the display area to the surrounding area;
forming a plurality of stacked films each including an organic layer which covers the lower electrode through the pixel aperture and which emits light in accordance with application of a voltage;
forming a first sealing layer formed of an inorganic insulating material to cover the plurality of stacked films;
forming a dam structure above the first partition in the surrounding area; and
forming a first resin layer provided inside the dam structure and covering the first sealing layer.

### Note 4

The display device manufacturing method of note 3, wherein
forming the dam structure is performed after the formation of the first sealing layer, and
the dam structure is in contact with the first sealing layer.

### Note 5

The display device manufacturing method of note 4, wherein
the first partition has a first end portion located above the inorganic insulating layer in the surrounding area,
the first sealing layer has a second end portion covering the first end portion, and
forming the dam structure forms an extending portion covering the second end portion.

### Note 6

The display device manufacturing method of note 5, wherein
the organic insulating layer has a third end portion located on an outer side than the first sealing layer in the surrounding area, and
forming the dam structure forms the extending portion covering the third end portion.

### Note 7

The display device manufacturing method of note 3, wherein
forming the dam structure is performed after the formation of the first partition, and
the dam structure is in contact with the first partition.

### Note 8

The display device manufacturing method of note 4, further including:
forming a second sealing layer formed of an inorganic material to cover the first resin layer; and
forming a third sealing layer formed of an inorganic material to cover the dam structure, after forming the dam structure and before forming the second sealing layer.

What is claimed is

1. A display device comprising:
a substrate having a display area and a surrounding area surrounding the display area;
an organic insulating layer provided over the display area and the surrounding area above the substrate;
a plurality of lower electrodes provided above the organic insulating layer in the display area;
an inorganic insulating layer including a plurality of pixel apertures overlapping with the plurality of lower electrodes, respectively;
a first partition including a first conductive lower portion provided above the inorganic insulating layer, and a first upper portion having an end portion protruding from a side surface of the first lower portion, and surrounding each of the plurality of pixel apertures;
a plurality of stacked films each including an organic layer which covers the lower electrode through the pixel aperture and which emits light in accordance with application of a voltage;
a first sealing layer formed of an inorganic insulating material to cover the plurality of stacked films;
a dam structure provided above the organic insulating layer, surrounding the first partition, and protruding farther than the first partition, in the surrounding area; and
a first resin layer provided inside the dam structure and covering the first sealing layer.

2. The display device of claim 1, wherein
the dam structure is covered with the inorganic insulating layer.

3. The display device of claim 2, wherein
an upper surface of the dam structure is located at a position higher than an upper surface of the first sealing layer.

4. The display device of claim 2, further comprising:
a second sealing layer formed of an inorganic material to cover the first resin layer, wherein
the second sealing layer is in contact with the inorganic insulating layer in an area outside the first resin layer.

5. The display device of claim 4, further comprising:
a second partition including a second lower portion provided above the inorganic insulating layer in the surrounding area, and a second upper portion having an end portion protruding from a side surface of the second lower portion, wherein
the second sealing layer covers the second partition.

6. A display device comprising:
a substrate having a display area and a surrounding area surrounding the display area;
an organic insulating layer provided over the display area and the surrounding area above the substrate;
a plurality of lower electrodes provided above the organic insulating layer in the display area;
an inorganic insulating layer including a plurality of pixel apertures overlapping with the plurality of lower electrodes, respectively; a first partition including a first conductive lower portion provided above the inorganic insulating layer, and a first upper portion having an end portion protruding from a side surface of the first lower portion, surrounding each of the plurality of pixel apertures in the display area, and provided from the display area to the surrounding area;
a plurality of stacked films each including an organic layer which covers the lower electrode through the pixel aperture and which emits light in accordance with application of a voltage;
a first sealing layer formed of an inorganic insulating material to cover the plurality of stacked films;
a dam structure provided above the first partition in the surrounding area; and
a first resin layer provided inside the dam structure and covering the first sealing layer.

7. The display device of claim 6, wherein
the stacked film and the first sealing layer are located between the first partition and the dam structure.

8. The display device of claim 7, wherein
the first partition has a first end portion located above the inorganic insulating layer in the surrounding area,
the first sealing layer has a second end portion covering the first end portion, and
the dam structure has an extending portion covering the second end portion.

9. The display device of claim 8, wherein
the organic insulating layer has a third end portion located on an outer side than the first sealing layer in the surrounding area, and
the extending portion covers both the second end portion and the third end portion.

10. The display device of claim 6, wherein
the dam structure is in contact with the first upper portion of the first partition.

11. The display device of claim 10, wherein
the stacked film and the first sealing layer are stacked in this order above the dam structure.

12. The display device of claim 11, further comprising:
a second sealing layer formed of an inorganic insulating material to cover the first resin layer; and
a second partition including a second lower portion provided above the inorganic insulating layer in the surrounding area, and a second upper portion having an end portion protruding from a side surface of the second lower portion, wherein
the second sealing layer covers the second partition.

13. The display device of claim 7, further comprising:
a second sealing layer formed of an inorganic material to cover the first resin layer; and
a third sealing layer formed of an inorganic material to cover the dam structure, wherein
the second sealing layer overlaps with the third sealing layer.

14. The display device of claim 13, wherein
the third sealing layer is provided on an outer side than the dam structure in the surrounding area.

15. The display device of claim 14, wherein
the third sealing layer is provided between the first sealing layer and the first resin layer in the display area.

16. The display device of claim 13, further comprising:
a second partition including a second lower portion provided above the inorganic insulating layer in the surrounding area, and a second upper portion having an end portion protruding from a side surface of the second lower portion, wherein
the second sealing layer covers the second partition.

17. The display device of claim 6, wherein
the first partition further includes a plurality of partition apertures in the surrounding area, and
the dam structure is provided between the plurality of partition apertures adjacent to each other.

18. The display device of claim 17, wherein
the first partition further includes a slit connecting the plurality of adjacent partition apertures with each other, and
the dam structure overlaps with the slit.

19. The display device of claim 17, wherein
the first partition further includes a slit connecting the plurality of adjacent partition apertures with each other, and
the dam structure does not overlap with the slit.

20. The display device of claim 1, further comprising:
a metal layer provided between the substrate and the organic insulating layer under the dam structure.
